(19) United States
(12) Patent Application Publication
(10) Pub. No.: US 2026/0149212 A1
(43) Pub. Date: May 28, 2026

(54) CONTACT ARRAY WITH FINE FEATURES FOR HIGH SPEED, HIGH DENSITY ELECTRICAL INTERCONNECTION

(71) Applicant: Amphenol Corporation, Wallingford, CT (US)

(72) Inventors: Barbara Andrea Calderon, Chelmsford, MA (US); Arkady Y. Zerebilov, Lancaster, PA (US); Dean Harmon, III, Etters, PA (US); Huilin Ren, Merrimack, NH (US); Marc B. Cartier, JR., Durham, NH (US); Donald A. Girard, JR., Bedford, NH (US)

(73) Assignee: Amphenol Corporation, Wallingford, CT (US)

(21) Appl. No.: 19/401,309

(22) Filed: Nov. 25, 2025

Related U.S. Application Data
(60) Provisional application No. 63/726,176, filed on Nov. 27, 2024.
(60) Provisional application No. 63/913,758, filed on Nov. 7, 2025.

(51) Int. Cl. H01R 13/422

(52) U.S. Cl. CPC H01R 13/422

(57) ABSTRACT

A compliant contact array for interconnecting conductive components in an electrical interconnect. The compliant contact array may include a plurality of features for contacting the conductive components. These and other features of the contact array may be relatively fine, such that contact arrays may make connections in a high density interconnection system or position metal to improve signal integrity, enabling high speed connectors. Further, features of the contact array may be shaped or positioned to provide desired mechanical properties such as a desired range of compliance and/or contact pressure. Features may control wall thickness of contact regions or enable telescoping or control the direction of flow of an elastomeric base region. The contact regions may be convex on one side and concave on another side. The compliant contact array may have a conductive layer applied thereon for electrically connecting the electrical connector to the conductive components.

### RELATED APPLICATIONS

This application claims the benefit of U.S. Provisional Application Ser. No. 63/726,176, filed on Nov. 27, 2024, under Attorney Docket No. A0863.70189US00 and entitled “CONTACT ARRAY WITH FINE FEATURES FOR HIGH SPEED, HIGH DENSITY ELECTRICAL INTERCONNECTION,”, and U.S. Provisional Application Ser. No. 63/913,758, filed on Nov. 7, 2025, under Attorney Docket No. A0863.70189US01 and entitled “CONTACT ARRAY WITH FINE FEATURES FOR HIGH SPEED, HIGH DENSITY ELECTRICAL INTERCONNECTION,” both of which are incorporated by reference herein in their entireties.

### FIELD

This patent application relates generally to interconnection systems, such as those including electrical connectors, used to interconnect electronic assemblies.

### BACKGROUND

Electrical connectors are used in many electronic systems. It is generally easier and more cost effective to manufacture a system as separate electronic assemblies, such as printed circuit boards (“PCBs”), which may be joined together with electrical connectors. A known arrangement for joining several printed circuit boards is to have one printed circuit board serve as a backplane. Other printed circuit boards, called “daughterboards” or “daughtercards,” may be connected through the backplane.

A known backplane is a printed circuit board onto which many connectors may be mounted. Conducting traces in the backplane may be electrically connected to signal conductors in the connectors so that signals may be routed between the connectors. In other systems, a backplane may be implemented with cables connecting signal conductors in connectors. The connectors may be mounted in a cartridge or similar support structure.

Daughtercards may also have connectors mounted thereon. The connectors mounted on a daughtercard may be plugged into the connectors of the backplane. In this way, signals may be routed among the daughtercards through the backplane. The daughtercards may plug into the backplane at a right angle. The connectors used for these applications may therefore include a right angle bend and are often called “right angle connectors.”

Connectors may also be used in other configurations for interconnecting printed circuit boards. Sometimes, one or more smaller printed circuit boards may be connected to another larger printed circuit board. In such a configuration, the larger printed circuit board may be called a “motherboard” and the printed circuit boards connected to it may be called daughterboards. Also, boards of the same size or similar sizes may sometimes be aligned in parallel. Connectors used in these applications are often called “stacking connectors” or “mezzanine connectors.” In yet other configurations, orthogonal boards may be aligned with edges facing each other. Connectors used in these applications are often called “direct mate orthogonal connectors.”

Connectors may also be used for interconnecting other types of components, such as cables, to printed circuit boards or other substrates, such as chip packages. In yet other system configurations, cables may be terminated to a connector, sometimes referred to as a cable connector. The cable connector may plug into a connector mounted to a printed circuit board such that signals that are routed through the system by the cables are connected to components on the printed circuit board.

Regardless of the exact application, electrical connector designs have been adapted to mirror trends in the electronics industry. Electronic systems generally have gotten smaller, faster, and functionally more complex. Because of these changes, the number of circuits in a given area of an electronic system, along with the frequencies at which the circuits operate, have increased significantly in recent years. Current systems pass more data between assemblies and require electrical connectors that are electrically capable of handling more data at higher speeds than connectors of even a few years ago.

In a high density, high speed connector, electrical conductors may be so close to each other that there may be electrical interference between adjacent signal conductors. To reduce interference, and to otherwise provide desirable electrical properties, shield members are often placed between or around adjacent signal conductors. The shields may prevent signals carried on one conductor from creating “crosstalk” on another conductor. The shield may also impact the impedance of each conductor, which may further contribute to desirable electrical properties.

Other techniques may be used to control the performance of a connector. For instance, transmitting signals differentially may also reduce crosstalk. Differential signals are carried on a pair of conducting paths, called a “differential pair.” The voltage difference between the conductive paths represents the signal. In general, a differential pair is designed with preferential coupling between the conducting paths of the pair. For example, the two conducting paths of a differential pair may be arranged to run closer to each other than to adjacent signal paths in the connector. Shielding is generally avoided between the conducting paths of the pair, but shielding may be used between differential pairs. Electrical connectors can be designed for differential signals as well as for single-ended signals.

Still, other techniques may be used to improve the performance of high density, high speed connectors. For example, the shapes and arrangement of the contacts of electrical connectors may be selected to optimize electrical performance. Specific arrangements may be selected which reduce crosstalk between conductors and/or improve the impedance performance of connectors.

In an electronic system, connectors may be attached to printed circuit boards or other substrates that include conductive traces to carry electrical signals, and power or ground planes. Sometimes, these conductive structures are on the surface of the substrate, but in other instances may be in the interior of the substrate. Connections to the these conductive structures may be made with holes drilled into the substrate, passing through the structures to be interconnected. These holes may be filled or plated with metal to form vias between the conductive structures through which the via passes.

Connectors may be mounted to the printed circuit board by electrically connecting conductive element from the connectors to conductive structures of the printed circuit board or other substrate. In some configurations, the conductive elements may have “tails” exposed for connection. The tails may be inserted into the vias or soldered to conductive pads on a surface of the printed circuit board. In other configurations a connector may have a pressure mount interface at which compliant mating contacts of conductive elements in the connector are exposed. The mating contacts may be pressed against pads on a surface of the substrate, making electrical connections.

### SUMMARY

Techniques for forming contact arrays in electrical interconnection systems are provided.

These techniques may be used alone or in any suitable combination. The foregoing is provided by way of illustration and is not intended to be limiting.

Some embodiments provide for a contact array for an electrical interconnection component, the contact array comprising: a contact region comprising an insulative elastic base region and a conductive coating on the base region; and an insulative web, integral with the contact region and supporting the contact region

Some embodiments provide for a contact array for an electrical interconnection component, the contact array comprising: a contact region comprising an insulative elastomer base region and a conductive coating on the base region, wherein: the insulative elastomer base of the contact region comprises at least one of a variation in thickness of the base region or a variation in surface contour of the base region on one or more surfaces of the insulative elastomer, and the conductive coating comprises a conductive ink.

Some embodiments provide for a contact array for an electrical interconnection component, the contact array comprising: an insulative elastomer member extending in a plane, the insulative elastomer member comprising a plurality of integral contact regions, wherein each of the plurality of contact regions comprises at least one insulative elastomer protrusion projecting transverse to the plane; and conductive coating on the at least one insulative elastomer protrusion of the plurality of contact regions.

Some embodiments provide for an electronic system, comprising: a substrate comprising a surface and a plurality of conductive pads on the surface; an interconnection component comprising a plurality of conductive members; and a contact array between the substrate and the interconnection component electrically connecting the plurality of conductive members to respective pads of the plurality of conductive pads, the contact array comprising an insulative elastomer base comprising a first side, adjacent the substrate and a second, opposite the first side, adjacent the interconnection component, wherein the contact array comprises a plurality of contact regions, each of the contact regions comprising a variation in a surface contour of the first side and/or the second side of the insulative elastomer base and a conductive coating on the insulative elastomer base.

Some embodiments provide for a method of connecting an electrical connector to a substrate with one or more conductive surfaces thereon, the method comprising: positioning the connector with a first surface of the connector facing a surface of the substrate and an elastomer contact array with protrusions aligned with the conductive surfaces; urging the connector towards the substrate such that the elastomer contact array contacts the one or more conductive surfaces of the substrate; and applying a mating force to the connector, whereby the protrusions of the elastomer contact array are deformed.

Some embodiments provide for a method of manufacturing an electrical connector, the method comprising: molding a contact array comprising a plurality of elastomer contact regions; and applying a conductive coating to at least the plurality of contact regions of the contact array, the conductive coating comprising a conductive ink.

Some embodiments provide for a method for assembling an electrical connector, the method comprising: providing a contact array comprising a plurality of elastomer contact regions; and assembling the contact array with a housing of the electrical connector, such that the contact array is supported by the housing.

### BRIEF DESCRIPTION OF DRAWINGS

The accompanying drawings are not intended to be drawn to scale. In the drawings, identical or nearly identical components that are illustrated in various figures may be represented by a like numeral. For purposes of clarity, not every component may be labeled in every drawing. In the drawings:

FIG. 1 is a bottom perspective view an exemplary electrical connector with a compliant contact array, according to some embodiments.

FIG. 2 is a schematic, side view of an electrical interconnection system having a compliant contact array, according to some embodiments.

FIG. 3 is an enlarged, sectional view of a portion of the electrical connector of FIG. 1.

FIG. 4A is a perspective view of a compliant conductive array configured for use the connector of FIG. 1 and having a plurality of protrusions, according to some embodiments.

FIG. 4B is an enlarged, sectional view of the electrical connector of FIG. 1 through a contact region, including a protrusion, of the compliant conductive array of FIG. 4A.

FIG. 4C is an enlarged perspective view of a portion of a surface of the compliant conductive array of FIG. 4A, sectioned through a protrusion.

FIG. 4D is a sectional view of a contact region of the compliant contact array of FIG. 4A, within an electrical connector and pressed against a substrate, such as a PCB.

FIG. 4E is a sectional view, normal to that of FIG. 4D, of a contact region of the compliant contact array of FIG. 4A, within an electrical connector and pressed against a substrate, such as a PCB.

FIG. 4F is a view of a protrusion of the compliant contact array of FIG. 4A in a compressed state.

FIG. 5A is a perspective view of an alternative embodiment of a compliant conductive array configured for use the connector of FIG. 1 and having a plurality of protrusions, according to some embodiments.

FIG. 5B is an enlarged, sectional view of the electrical connector of FIG. 1 through a contact region, including a protrusion, of the compliant conductive array of FIG. 5A.

FIG. 5C is an enlarged perspective view of a portion of a surface of the compliant conductive array of FIG. 5A, sectioned through a protrusion.

FIG. 5D is a sectional view of a contact region of the compliant contact array of FIG. 5A, within an electrical connector and pressed against a substrate, such as a PCB.

FIG. 5E is a sectional view, normal to that of FIG. 5D, of a contact region of the compliant contact array of FIG. 5A, within a PCB and pressed against a substrate, such as a PCB.

FIG. 5F is a view of a protrusion of the compliant contact array of FIG. 5A in a compressed state.

FIG. 5G is a view of a protrusion of the compliant contact array of FIG. 5A in a compressed state and shaded according to the pressure at the interface of a protrusion and a substrate.

FIG. 5H is a view of a protrusion of the compliant contact array of FIG. 5A in a compressed state and shaded according to the pressure at the interface of a protrusion and a conductive element of an electrical connector.

FIG. 5I is a view of a protrusion of the compliant contact array of FIG. 5A in a compressed state and shaded according to the elastic strain within the compliant contact array.

FIG. 6A is a perspective view of an alternative embodiment of a compliant conductive array configured for use the connector of FIG. 1 and having a plurality of protrusions, according to some embodiments.

FIG. 6B is an enlarged, sectional view of the electrical connector of FIG. 1 through a contact region, including a protrusion, of the compliant conductive array of FIG. 6A.

FIG. 6C is an enlarged perspective view of a portion of a surface of the compliant conductive array of FIG. 6A, sectioned through a protrusion.

FIG. 6D is a sectional view of a contact region of the compliant contact array of FIG. 6A, within an electrical connector and pressed against a PCB.

FIG. 6E is a sectional view, normal to that of FIG. 6D, of a contact region of the compliant contact array of FIG. 6A, within an electrical connector and pressed against a PCB.

FIG. 6F is a view of a protrusion of the compliant contact array of FIG. 6A in a compressed state.

FIG. 7A is a perspective view of an alternative embodiment of a compliant conductive array configured for use the connector of FIG. 1 and having a plurality of protrusions, according to some embodiments.

FIG. 7B is an enlarged, sectional view of the electrical connector of FIG. 1 through a contact region, including a protrusion, of the compliant conductive array of FIG. 7A.

FIG. 7C is an enlarged perspective view of a portion of a surface of the compliant conductive array of FIG. 7A, sectioned through a protrusion.

FIG. 7D is a sectional view of a contact region of the compliant contact array of FIG. 7A, within an electrical connector and pressed against a PCB.

FIG. 7E is a sectional view, normal to that of FIG. 7D, of a contact region of the compliant contact array of FIG. 7A, within an electrical connector and pressed against a PCB.

FIG. 7F is a view of a protrusion of the compliant contact array of FIG. 7A in a compressed state.

FIG. 8A is a perspective view of an alternative embodiment of a compliant conductive array configured for use the connector of FIG. 1 and having a plurality of protrusions, according to some embodiments.

FIG. 8B is an enlarged, sectional view through a contact region, including a protrusion, of the compliant conductive array of FIG. 8A.

FIG. 8C is an enlarged perspective view of a portion of a surface of the compliant conductive array of FIG. 8A, sectioned through a protrusion.

FIG. 9A is a perspective view of an alternative embodiment of a compliant conductive array configured for use the connector of FIG. 1 and having a plurality of protrusions, according to some embodiments.

FIG. 9B is an enlarged, sectional view through a protrusion of a contact region of the compliant conductive array of FIG. 9A.

FIG. 9C is an enlarged, sectional view through the compliant conductive array of FIG. 9A, taken adjacent a protrusion of a contact region.

FIG. 9D is an enlarged, bottom perspective view of a portion of a surface of the array of FIG. 9A including a contact region.

FIG. 10A is a perspective view of an alternative embodiment of a compliant conductive array configured for use the connector of FIG. 1 and having a plurality of protrusions, according to some embodiments.

FIG. 10B is an enlarged, sectional view through a protrusion of a contact region of the compliant conductive array of FIG. 10A.

FIG. 10C is an enlarged, perspective view of a portion of a surface of the array of FIG. 10A including a contact region.

FIG. 11A is a perspective view of an alternative embodiment of a compliant conductive array configured for use the connector of FIG. 1 and having a plurality of protrusions, according to some embodiments.

FIG. 11B is an enlarged, sectional view adjacent a protrusion of a contact region of the compliant conductive array of FIG. 11A.

FIG. 11C is an enlarged, bottom perspective view of a portion of a surface of the array of FIG. 11A including a contact region.

FIG. 12A is an exploded view of an alternative exemplary electrical connector having a compliant contact array, according to some embodiments.

FIG. 12B is a sectioned view through a portion of the connector of FIG. 12A.

FIG. 12C is a plot showing a relationship between displacement (in micrometers) and compressive force (in kgf) for fine featured contact arrays.

FIG. 12D is a sectioned view of an alternative embodiment of a flexible contact array in which contact regions have a solid cross section and a higher stiffness than the cross section of FIG. 12B.

FIG. 13 is an enlarged, bottom perspective view of a portion of a surface of a compliant conductive array, including a contact region, which may be used in a connector as in FIG. 12A, according to some embodiments.

FIG. 14 is an enlarged, bottom perspective view of a portion of a surface of an alternative embodiment of a compliant conductive array, including a contact region, which may be used in a connector as in FIG. 12A, according to some embodiments.

FIG. 15A is a perspective view of a compliant conductive array configured for use in an electrical connector as illustrated in FIG. 12A and having a plurality of protrusions, according to some embodiments.

FIG. 15B is an enlarged perspective view of a portion of a surface of the compliant conductive array of FIG. 15A.

FIG. 15C is an enlarged, sectional view of the compliant conductive array of FIG. 15A through a contact region, including a protrusion.

FIG. 15D is a sectional view of a contact region of the compliant contact array of FIG. 15A, within an electrical connector and pressed against a PCB.

FIG. 16A is a perspective view of a compliant conductive array configured for use in the electrical connector of FIG. 12A and having a plurality of protrusions each with multiple contact projections, according to some embodiments.

FIG. 16B is an enlarged perspective view of a portion of a pressure mount face of an electrical connector including the compliant conductive array of FIG. 16A.

FIG. 16C is an enlarged side view of a contact region of the compliant conductive array of FIG. 16A coupled to an electrical connector.

FIG. 16D is an enlarged side view of a contact region of the compliant conductive array of FIG. 16A coupled to an electrical connector and pressed against a PCB.

FIG. 16E is an enlarged side view of a contact region of the compliant conductive array of FIG. 16A coupled to an electrical connector and pressed against a PCB, and shaded based on the sliding distance of the compliant contact array along a conductive element of an electrical connector.

FIG. 16F is an enlarged view of a contact region of the compliant conductive array of FIG. 16A in a compressed state, and shaded based on the stress within the compliant contact array.

FIG. 17A is a perspective view of a compliant conductive array configured for use in the electrical connector of FIG. 12A and having a plurality of protrusions each with multiple contact projections, according to some embodiments.

FIG. 17B is an enlarged perspective view of a portion of the compliant conductive array of FIG. 17A.

FIG. 17C is an enlarged, sectional view of the compliant conductive array of FIG. 17A through a contact region, including a protrusion.

FIG. 17D is an enlarged side view of a contact region of the compliant conductive array of FIG. 17A coupled to an electrical connector and pressed against a PCB.

FIG. 18 is a perspective view of a cable connector which may include compliant conductive structures, according to some embodiments.

FIG. 19 is a perspective view of an exemplary embodiment of an attachment region of a cable module, with a compliant shield, that may be used in a connector as shown in FIG. 18.

### DESCRIPTION OF PREFERRED EMBODIMENTS

The inventors have recognized and appreciated techniques for forming contact arrays that facilitate high speed and high density electrical interconnects, such as electrical connectors. Such contact arrays may be formed with insulative elastic material, which may form a base region for one or more contact regions. The contact region(s) may be supported by a web, which may be insulative. The web may enable the base region(s) to be positioned where an electrical connection is to be made between two conductive elements of components that are to be connected through the contact array. Each of the one or more base regions may have a conductive coating, which may form a conducting path between the conductive elements when the components are pressed together with the contact array between them.

Such a contact array may be used in any of multiple types of electrical interconnects. It may be used, for example, between a pressure mount connector and a surface of a printed circuit board acting as a substrate on which the pressure mount connector is mounted. Alternatively or additionally, such a contact array may be used between a shield of a cable connector and a shield of a cable terminated to the cable connector. In some examples, the conducting paths may connect ground structures and provide a path for ground current to flow. In other examples, the conducting paths may provide signal paths. In yet other examples, the conducting paths may provide both ground and signal connections.

The elastic base material may have a Poisson ratio of approximately 0.5, indicating that, when subjected to a compressive force, the material largely flows to reduce its thickness without undergoing a reduction in overall volume. Elastic materials as described herein, for example, may have a Poisson ratio of 0.5+/−0.1 or 0.5+/−0.05 , in some examples. Elastic materials may be formed with features having a separation to deflection ratio, the ratio of the spread of the material in a plane to the deflection of the material in a direction parallel to a force applied to the material, of less than 2 in some examples. Elastic materials as described herein may be soft and may have, for example, a hardness between 2 Shore A and 5 Shore A, between 2 Shore A and 20 Shore A, between 2 Shore A and 50 Shore A, between 2 Shore A and 90 Shore A, between 2 Shore A and 100 Shore A, or between 10 Shore A and 90 Shore A. The elastic base region may be formed from an elastomer. Liquid silicone rubber, for example, may be molded into a desired shape with multiple base regions in an array held together by a web. In such an example the web and base regions may be integrally formed. In other examples, the web and base regions may be formed separately and may have different material properties. As a specific example, the web may be molded of an insulative or lossy material, such as a thermoplastic or a thermoplastic filled with conducting particulates, or stamped from a sheet of metal. In either case, the elastic material may be deposited onto the web. Examples of elastic materials that may be used for compliant contact arrays, as described herein, may include liquid silicone rubber, neat polymers and other similar materials. In some examples, materials with elastic properties may be used, for example foamed materials (e.g., elastomeric foams, silicone foams, etc.).

The insulative elastic base material may be shaped to provide fine geometries, such as by injecting the material in liquid form into a mold and curing it in a shape that conforms to the mold. These fine geometries may be used in features of the contact array to provide characteristics such as closely spaced contact regions and/or contact regions that engage with conducting parts that have non-planar surfaces or irregular shapes. Alternatively or additionally, contacts in an array with fine geometries may make contact with conducting elements over a wide range of separations and/or operate with a large amount of compressive displacement without yielding. This capability, for example, may ensure reliable mating between two components containing the conductive elements that provides high signal integrity connections even in high density interconnects in which the interconnection structures are closely spaced and/or may vary from a nominal location based on manufacturing tolerances.

Alternatively or additionally, the force required to deform the contact region to accommodate conducting elements separated by any distance in the range may be controlled by features of the base region. This capability, for example, may enable connectors with relatively low mating force to make high quality connections, which may simplify operation of a connection system and/or improve its performance. Alternatively or additionally, the contact region may be shaped to have an envelope before and/or after compression that provides a desired separation between the contact region and adjacent conductive elements. This capability, for example, may enable contact regions separated to limit crosstalk between conductive elements and/or to provide a consistent separation between signal conductors and grounds so as to control impedance through the contact array.

In some examples, the thickness and/or surface contour of the compliant contact array may vary across the array. For example, the compliant contact array may include features such as protrusions on a first side of the array, configured to contact a substrate (e.g., a PCB). Additionally, or alternatively, the side of the compliant contact array, opposite the first side, may have variations in surface contour, such as may be provided cavities corresponding to the locations of protrusions on the array. Different surface contours on opposite sides of the contact array may yield different thickness of the array in different locations.

Features, such as protrusions and/or other surface contours, of a compliant contact array may be configured to provide desired force responses. For example, compliant contact arrays can be designed to have a shallow stress-strain curve from compression, which reduces material fatigue and provides reliable connections. In some examples, the base regions may be formed with features shaped to fold or collapse when a force is applied to the compliant contact array. Such a configuration, for example, may enable each contact region to make reliable connections between two conductive elements over a large range of separations between the conductive elements. Alternatively or additionally, features of the base regions may be shaped such that the base region changes shape in a desired fashion when placed under a compressive force. For example, the features may be designed to deform in a way that does not increase the footprint of the compliant contact array, such as by telescoping or otherwise compressing with lateral movement of the elastic material that does not extend beyond a predetermined separation from an adjacent conductor. Including features to control the expansion of the envelope bounding each contact region when placed under a mating force may prevent contact regions of the array from getting sufficiently close to an adjacent contact region or an adjacent conductive element so as to short, increase crosstalk, or to change the impedance of the conductive paths through the interconnect. The features may provide an expansion of the cross sectional area of the contact region, in a plane perpendicular to a compression direction, of less 20%, and in some examples less than 10% or less than 5%. The features may also be designed to provide desired levels of deformation at specific mating forces.

In some examples, the features may be shaped to change their shape, such as via collapsing, folding, deforming and/or compressing in a certain manner. A stepped shape may enable a feature to collapse, for example. A cavity may be provided as part of the base region to provide a desired compliance, deflection, deformation, collapsing or folding. A cavity between the base region and an insulative web supporting the base region may provide desired compliance, deflection, deformation, material flow, collapsing or folding. As another example, a feature may be a membrane, thinner than an insulative web forming a portion of the contact array. A membrane may have a thickness or shape to provide desired compliance, deflection, deformation, material flow, collapsing or folding. Features may be provided adjacent to each other to provide desired compliance, deflection, deformation, material flow, collapsing or folding. For example, holes may be provided adjacent to a protrusion which may control the deformation of the protrusion.

Alternatively or additionally, the feature may be a tapered cross section in a plane including the direction of mating force. Alternatively or additionally, holes in or through the contact array can allow for compliance, deflection, deformation, material flow, collapsing or folding with desired mechanical properties. The holes may be at a central portion of contact regions, for example, such that, when a force is applied to the contact array, elastic material of the contact region may flow into the hole, reducing the stiffness of the contact region. As another example, holes adjacent to a protrusion may enable an increased change in height of the protrusion when subjected to a force within a range of desired mating forces. Characteristics of the holes may be selected to alter the behavior of the protrusion when placed under a compressive force. Larger holes, holes with thinner sidewalls, and holes closer to the protrusion, for example, may enable increased change in height of the protrusion under the same compressive force than similar structures without the holes. Holes may have any of multiple shapes, including for example circular, oblong, or rectangular, among other shapes, which may control the deformation of the protrusion.

In some examples, the materials used to form the compliant contact array may be such that the changes in shape as a result of compression of the contact array are reversible. The material may return to substantially its original shape when the compressive force, even after multiple mating cycles.

Dimensions of features may be selected to provide desired levels of compliance, deflection, deformation, collapsing or folding. For example, the features may be positioned to decrease the wall thickness of portions of the contact regions to decrease stiffness of the contact array. Alternatively or additionally, features that increase wall thickness may be positioned to increase stiffness. Features may be provided with varying dimensions to control the compliance, deflection, deformation, collapsing or folding. The heights and/or lengths of the features may be selected to provide desired compliance, deflection, deformation, collapsing or folding, and/or may be selected for contacting specific conductive structures.

Such contact arrays may be used to provide desired current flow paths between conductive structures of two components to be electrically connected. For example, contact arrays may be used to make some or all of the connections between an electrical connector and another component. For example, compliant contact arrays may be used to make ground connections in conjunction with signal contacts of other types. As a specific example, a compliant contact array may connect a ground shield of a cable to pads of a PCB while signal conductors of the cable are connected to pads of the PCB either directly or through other intermediate structures.

Such contact arrays may be made (e.g., via molding) of a material with low viscosity in its uncured state, for example, in a range of 0.015 Pa·s to 13000 Pa·s., 1 Pa·s-13,000 Pa·s, 1 Pa·s-10,000 Pa·s, 1 Pa·s-5,000 Pa·s, 1 Pa·s-2500 Pa·s, 1 Pa·s-2000 Pa·s, 1 Pa·s-1,000 Pa·s, 1 Pa·s-500 Pa·s, 1 Pa·s-300 Pa·s, 1 Pa·s-200 Pa·s, 1 Pa·s-100 Pa·s, 5,000 Pa·s-15,000 Pa·s, 5,000 Pa·s-10,000 Pa·s, 1,000 Pa·s-15,000 Pa·s, 1,000 Pa·s-10,000 Pa·s, 1,000 Pa·s-5,000 Pa·s, 10 Pa·s-500 Pa·s, 10 Pa·s-300 Pa·s, 10 Pa·s-200 Pa·s, 10 Pa·s-100 Pa·s, 50 Pa·s-500 Pa·s, 50 Pa·s-300 Pa·s, 50 Pa·s-200 Pa·s, 50 Pa·s-100 Pa·s, 100 Pa·s-500 Pa·s, 100 Pa·s-300 Pa·s, 100 Pa·s-250 Pa·s, 100 Pa·s-200 Pa·s, 0.001 Pa·s-1,000 Pa·s, 0.001 Pa·s-500 Pa·s, 0.001 Pa·s-250 Pa·s, 0.001 Pa·s-100 Pa·s, 0.001 Pa·s-10 Pa·s, or 0.001 Pa·s-1 Pa·s, including any value or range of values within such ranges. Such a material with low viscosity enables the compliant contact array to have fine features with small dimensions, for example, in the range of 0.05 mm to 0.8 mm, and to be thin, for example, in the range of 0.01 mm to 0.5 mm, including any value or range of values within such range. Moreover, the contact array may extend in a plane with variations in thickness over this plane such that the mechanical properties of contact regions may be set to desired values by shaping the features of the base regions that become the contact regions. Low viscosity material that cures into elastic material enables molding of contact arrays, such that the array may have fine features. Those features might be finer than might be achieved via stamping. Further, the resulting components may be more robust than those made of foamed materials.

A low viscosity material may be, for example, liquid silicone rubber, which may be injection molded into small and complex features due to its low viscosity. The high flowability of this material and fast curing time makes the injection molding process practical for manufacturing. The resultant molded part is resilient and resistant to tearing, which facilitates deflashing/deburring without damage to the molded parts.

According to some embodiments, a compliant contact array may include portions made of an elastomer and optionally may include portions made of thermoplastic.

In some examples, the low viscosity materials may include conductive particles when molded. The conductive particles may be metal spheres or metal or carbon fiber, for example. In other examples, the low viscosity material may be neat material, substantially free of fillers. As a specific example, the material used to form the base regions and connecting web, if present, may be greater than 80% polymer, and in some examples, greater than 85%, 90% or 95% polymer when cured. For example, an unfilled elastomer may provide more desirable material characteristics including, for example, lower viscosity, higher tear strength, and/or lower durometer hardness than filled conductive elastomer.

In other examples, a base of a contact array may be molded of a neat material, which may be regarded as insulative and may have, for example, a resistivity of at least 10⁵ Ωcm, and may be higher in some examples such as at least 10⁸ Ωcm, or at least 10¹⁰ Ωcm. Conductivity through or along the array may be provided by a conductive coating on the base. A conductive coating, for example, may be applied as a conductive ink. A conductive ink may contain a solvent with highly conductive particles, such as silver particles. After application, the solvent may evaporate, leaving a conductive coating. Contact regions may be formed by selectively depositing conductive ink on the base.

In some examples, the conductive layer may be a silicone silver paste. In some embodiments, the conductive layer has a thickness of any value between 10-500 μm, between 10-400 μm, between 10-300 μm, between 10-200 μm, between 10-100 μm, between 20-100 μm, between 30-100 μm, between 40-100 μm, and/or between 50-100 μm. In some examples, the conductive layer may be applied in multiple layers. In some examples, the conductive layer may be selectively applied to different portions of the compliant contact array to provide one or more conductive paths across the contact array.

Contact regions may be formed with a conductive layer extending along surfaces of insulative base regions. For example, a conductive ink may be applied to surfaces of one or more base regions shaped to provide mechanical properties, such as those described above. The insulative base regions may be shaped to provide surfaces that may be covered by the conductive ink for providing current flow paths in locations relative to signal conductors that provide desirable signal integrity for signals carried by the signal conductors.

In an array with multiple contact regions, the coating may be applied selectively to provide electrically separated contact regions. Alternatively or additionally, the conductive coating may be applied on portions of the base interconnecting contact regions such that some or all of the contact regions of the array are electrically interconnected.

The location and extent of the conductive coating may define current flow paths in any of multiple locations, such as between shields within a connector when the contact array is pressed against the connector or between ground structures of a connector and another component such as a printed circuit board to which the connector is to be mounted with the contact array compressed between the connector and the other component. These current flow paths may be accurately positioned, and the positional accuracy may be greater than with conductive paths formed with filled conductive elastomers, for example, in which current flow paths may have a lower positioning accuracy due to filler segregation and/or low filler dispersion within small features.

Such a contact array may allow for larger tolerances for connectors, conductive components, and electrical connection systems. The protrusions may provide improved connections and increased tolerances as the protrusions provide electrical connection across a range of distances and forces applied to the connection system and can provide stable connections at low mating forces. Further the compliant contact arrays can account for variations in conductive features because the contact regions may be formed with a large range of distances over which they can maintain connections. The compliant contact arrays may also be less susceptible to vibrations, stress relaxations and/or heat such that they maintain material properties that facilitate reliable connections longer than metal contact arrays.

Such compliant contact arrays may be used in an electrical connector to provide a high density of connections. The contact arrays, with multiple contact regions enable conductive elements to be closely spaced. The compliant contact arrays disclosed herein may support high density connectors such as those designed to have pitches for pairs in an array, such as a pair-to-pair pitch of 3.2 mm×3 mm, 2.4 mm×2.4 mm, 1.8 mm×2 mm, or smaller. A contact array with one or more of the features described herein may be used in a connector with limited spaces for compliant contacts while nonetheless providing stable electrical connections. In some examples, contacts may fit within spaces with a minimum dimension in the range of 0.1 mm to 0.5 mm, including any value or range of values within such range. The compliant contact arrays disclosed herein may enable desirable performance for the high density connectors at high frequencies to support high data rates including at 112 Gbps and above.

In some examples, the compliant contact array may be mounted to an electrical connector, for example at a pressure mount face of an electrical connector. A compliant contact array may be pressed against an electrical connector. Such pressure may result from the compliant contact array being between the connector and a substrate to which the connector is to be mated, and pressing the connector against the substrate. A compliant contact array may be mounted to an electrical connector via a retaining member, for example a retaining member with one or more bars or similar features that hold the compliant contact array against the electrical connector. In some examples, connectors may be mated to a substrate via interaction with one or more pressure generating components, for example one or more fasteners and/or plates that apply a force to the connectors that press them towards the substrate. The compliant contact array may be configured to contact conductive features of the electrical connector at a first side of the contact array. The compliant contact array may be configured to contact conductive structures such as a cable shield, a shielding member, a cable, conductors, conductive leads, and/or conductive beams of the electrical connector, among other conductive features. In some examples, the compliant contact array may be configured to contact conductive structures used for power transmission, ground current flow, shielding and/or signal transmission.

In some examples, the compliant contact array alternatively or additionally may be configured to connect to conductive features at a second side of the contact array. For example, the compliant contact array may be configured to connect to pads of a PCB or other substrate, among other conductive features. In some examples, a surface of the compliant contact array is configured to contact the conductive features. In some embodiments, the compliant contact array may include features that are configured to contact the conductive features. For example, the compliant contact array may include protrusions configured to contact the conductive features.

In some examples, the protrusions may be shaped to provide desired properties. In some embodiments, the protrusions may be circular, rectangular, rhombus-shaped, oblong, or may have other suitable shapes, in a plane of the compliant contact array.

In some examples, the cross-sectional shape, in a plane perpendicular to the plane of the compliant contact array, of the protrusions may be selected to provide desired properties. In some embodiments, the protrusions may have a convex cross section shape, which in some examples may be on the side of the compliant contact array configured to contact the PCB or other component. Optionally, the protrusions may have a concave cross section shape on the side of the compliant contact array configured to contact conductive features of an electrical connector. In some embodiments, the protrusions may include one or more steps in their cross sections, which allow the protrusion to collapse or fold, responsive to a mating force. Optionally, the protrusions may have a cross section that is partially or entirely circular, oval, rectangular, and/or trapezoidal. Optionally, there may be a cavity or recess in the compliant contact array on the side of the array configured to contact conductive features of an electrical connector, which the protrusions may fold into. In some embodiments, protrusions may have one or more holes therein.

In some examples the protrusions may be dimensioned to make reliable connections between two conductive structures separated by a distance, and that distance may be within a range that accommodates manufacturing and/or operational tolerances in an electronic system or other sources of variability in the separation of mated conductive structures in the interconnect. To support such functionality, the protrusions may be dimensioned to provide desired levels of compression, deformation, collapsing or folding, at specific mating forces. In some embodiments, mating forces may be transferred to compliant contact arrays through features of an electrical connector, for example ribs aligned with the compliant contact array. Optionally, the protrusions may be configured to compress by desired amounts at specific mating forces. For example, protrusions may be configured to compress up to 15%, up to 20%, up to 25%, up to 30%, up to 35%, up to 40%, up to 45% or up to 50%, responsive to a mating force of 10 grams-force per protrusion. In some examples, protrusions may be configured to compress up to 15%, up to 20%, up to 25%, up to 30%, up to 35%, up to 40%, up to 45% or up to 50%, responsive to a mating force of 12 grams-force per protrusion. In some examples, protrusions may be configured to compress up to 15%, up to 20%, up to 25%, up to 30%, up to 35%, up to 40%, up to 45% or up to 50%, responsive to a mating force of 14 grams-force per protrusion. In some examples, protrusions may be configured to compress up to 15%, up to 20%, up to 25%, up to 30%, up to 35%, up to 40%, up to 45% or up to 50%, responsive to a mating force of 16 grams-force per protrusion. In some examples, protrusions may be configured to compress up to 15%, up to 20%, up to 25%, up to 30%, up to 35%, up to 40%, up to 45% or up to 50%, responsive to a mating force of 20 grams-force per protrusion. In some examples, protrusions may be configured to compress up to 15%, up to 20%, up to 25%, up to 30%, up to 35%, up to 40%, up to 45% or up to 50%, responsive to a mating force of between 10-15 grams-force per protrusion. In some examples, protrusions may be configured to compress up to 15%, up to 20%, up to 25%, up to 30%, up to 35%, up to 40%, up to 45% or up to 50%, responsive to a mating force of between 5 -15 grams-force per protrusion. In some examples, protrusions may be configured to compress up to 15%, up to 20%, up to 25%, up to 30%, up to 35%, up to 40%, up to 45% or up to 50%, responsive to a mating force of between 5-20 grams-force per protrusion. In some examples, protrusions may be configured to compress up to 15%, up to 20%, up to 25%, up to 30%, up to 35%, up to 40%, up to 45% or up to 50%, responsive to a mating force of between 15-20 grams-force per protrusion. In some examples, protrusions may be configured to compress up to 15%, up to 20%, up to 25%, up to 30%, up to 35%, up to 40%, up to 45% or up to 50%, responsive to a mating force of between 2-15 grams-force per protrusion. In some examples, protrusions may be configured to compress up to 15%, up to 20%, up to 25%, up to 30%, up to 35%, up to 40%, up to 45% or up to 50%, responsive to a mating force of between 2-10 grams-force per protrusion. In some examples, protrusions may be configured to compress up to 15%, up to 20%, up to 25%, up to 30%, up to 35%, up to 40%, up to 45% or up to 50%, responsive to a mating force of between 2-5 grams-force per protrusion.

Compliant contact arrays may compress when an electrical connector is mounted to a substrate. Features of the compliant contact arrays, such as the thickness, lengths, and/or shapes of protrusions may be selected to control the amount of compression of the contact array. In some examples, compliant contact arrays may compress between 0.1-1 mm, between 0.05-1 mm, between 0.05-0.5 mm, between 0.05-0.25 mm, between 0.05 mm- 0.2 mm, or between 0.1-0.2 mm. Such levels of compression may be achieved at specific contact forces, for example a contact force of less than 500 grams-force, less than 250 grams-force, less than 150 grams-force, less than 130 grams-force, less than 100 grams-force, less than 50 grams-force, less than 10 grams-force, or about 5 grams force in some examples. Protrusions may extend from a plane of a compliant contact array (e.g., a plane of the web of a compliant contact array). Protrusions may extend between 0.1-1.0 mm from a plane of the compliant contact array, between 0.1-0.5 mm from a plane of a compliant contact array, or between 0.2-0.5 mm from a plane of the compliant contact array.

In some examples, a compliant contact array is configured to provide a stable electrical connection between conductive elements of the electrical connector and other conductive elements, such as pads of a PCB, at low mating forces. For example, in some embodiments, a compliant contact array may provide a stable connection of 6-9 milliohms of contact resistance at specific contact forces, for example a contact force of less than 500 grams-force, less than 250 grams-force, less than 150 grams-force, less than 130 grams-force, less than 100 grams-force, less than 50 grams-force, less than 10 grams-force, or about 5 grams force in some examples. In some examples, a stable contact resistance, varying less than +/−3 milliohms, such as less than +/−1 milliohm for example, may be achieved with a contact force between 5-500 grams-force, between 6-250 grams force, between 6-135 grams force, between 6-100 grams force, between 6-15 grams-force, per contact location, for example. In some examples, such stability may be achieved even in the presence of a temperature variation from ambient to in excess of 100 degrees C.

Compliant contact arrays such as those described herein may be included within electrical connectors and configured to form electrical connections with conductive elements (e.g., conductive pads of a PCB or shields or signal conductors of the connector). In such examples, electrical connections between the compliant contact arrays and the conductive elements may be formed with a mating force of approximately 1-50 grams force per contact point, over a compression range of the compliant contact array of 0.05-0.5 mm. Further, in some examples, compliant contact arrays may maintain stable electrical connections over a compression range. For example, compliant contact arrays may maintain an electrical connection with 10 Milliohms to 950 milliohms from a compression range of 5% to 80 % of the thickness of a compliant contact array. In some examples the electrical connection may have a resistance of between 5-950 milliohms, 5-100 milliohms, 5-10 milliohms, or less than 5 milliohms.

The inventors have further appreciated designs of compliant contact arrays that improve the stability of electrical connections between compliant contact arrays and conductive elements (e.g., conductive shields, surface of a PCB, etc.). The inventors have recognized and appreciated designs of compliant contact features that provide wipe along conductive elements connected to or through a compliant contact array and improve the electrical contact between the contact array and the conductive elements. Wiping along the conductive elements clears dust, residue, oxidation and other contaminants that may impact the quality of connection between the compliant contact array and a conductive element. In some examples, compliant contact arrays may be configured to wipe between 0.01-0.5 mm along a conductive element, between 0.01-0.25 mm, or between 0.1-0.25 mm, at the interface between the compliant contact array and the conductive elements.

In some examples, compliant contact arrays may include features that facilitate wipe along conductive elements (e.g., conductive shields, pads of a PCB, etc.) For example, the protrusions of a compliant contact array may be configured to deform as they are compressed such that a contact location between the protrusion and the conductive structure changes with greater compression. Such a change in shape may be used, for example, to provide wipe along pads of a PCB or other substrate as the compliant contact array is urged towards the substrate (e.g., during a mating process for an electrical connector). The protrusions of a compliant contact array may, in some examples, include multiple contact projections that wipe along the pad of a PCB as the protrusion is compressed responsive to a mating force.

In some examples, the motion of the contract location between a projection of a contact array and a conductive element may be orthogonal to the direction in which the projection is compressed. In other examples, the motion of the relative position of the contact locations may be in other directions. The contact regions of compliant contact arrays may be configured to wipe along conductive elements of an electrical connector (e.g., conductive shields) regardless of the orientation of those surfaces relative to the mating interface of the connector. The contact regions may wipe along conductive elements by virtue of the compliance of the array. For example, during a mating process for an electrical connector, contact between a protrusion of a contact region and a pad of a PCB, may cause the contact region to deflect and wipe along surfaces of shields of the electrical connector that are perpendicular or otherwise transverse to the orientation of the pads. Additionally, or alternatively contact regions of compliant contact arrays may include features to facilitate wiping against conductive elements of an electrical connector. For example, contact regions may be offset relative to the base of a compliant contact array to provide greater space for deflection and thus wipe along conductive features of an electrical connector. Features for facilitating wiping of protrusions and/or other features of compliant contact arrays along conductive elements may be combined with other features of compliant contact arrays as described herein.

The inventors have additionally appreciated that a compliant contact array may be made with materials and/or contact shapes that support deformation at low forces that enables contact surfaces of the contact array to conform to contact surfaces of a mating component, despite asperities or other variation across the contact surfaces of the conductive elements of a mating component. Conforming the contact surfaces may reduce contact resistance, even at low contact forces. A compliant contact array with this characteristic may enable dense connectors in which multiple connections are made when the connector is mated to a substrate.

The inventors have additionally recognized and appreciated designs of contact arrays that increase the contact force per unit of contact surface between compliant contact arrays and conductive elements (e.g., pads of a PCB, shields of an electrical connector, etc.). Such designs may also improve the electrical connection between the compliant contact array and conductive elements. Higher contact pressure, for example, may improve how well contact surfaces of the compliant contact array conform to the surface of the conductive element and thus reduces the impact of contact asperities on contact resistance. Alternatively or additionally, increased contact pressure may lessen the impact of oxide or other contaminants on the contact surfaces.

In some examples, compliant contact arrays may include features for increasing the contact pressure at interfaces between the compliant contact array and conductive elements. For example, protrusions of the contact regions of a compliant contact array may be tapered and/or include raised bumps, steps, projections or other similar features which increase the contact pressure at the interfaces between the protrusions and conductive elements such as pads of a PCB or other substrate. Additionally, or alternatively, contact regions of compliant contact arrays may include features for increasing the contact pressure between a compliant contact array and conductive elements of an electrical connector, such as shields. For example, contact regions of compliant contact arrays may include bumps along the interface between the contact regions and conductive elements of an electrical connector, which increase the contact pressure at the interface between the contact regions and the conductive elements. The features of the compliant contact array for increasing contact pressure between the compliant contact array and conductive elements (e.g., pads of a PCB, shields of an electrical connector, etc.) may increase the contact pressure at the interface(s) between the compliant contact array and conductive elements while maintaining relatively low mating forces for electrical connectors including compliant contact arrays. This capability is facilitated by forming the base of the compliant contact array with a material that may be molded with fine features. Liquid silicone rubber, neat polymers and other similar materials may be molded into a base with features that provide increased contact pressure, for example. Features of compliant contact arrays for increasing the contact pressure at interfaces between compliant contact arrays and conductive may be combined with other features of compliant contact arrays as described herein. In some examples, compliant contact arrays are configured to achieve contact pressures of at least 0.5 MPa, at least 1 MPa, at least 2 MPa, at least 5 MPa, between 1-5 MPa, between 1-10 MPa, between 1-50 MPa, between 1-100 MPa, between 1-500 MPa, between 1-1000 MPa, between 1-1400 MPa, between 1-1500 MPa or between 1 MPa and greater than 1500 MPa, at interfaces between the compliant contact array and conductive element (e.g., pads of a PCB, shields of an electrical connector, etc.).

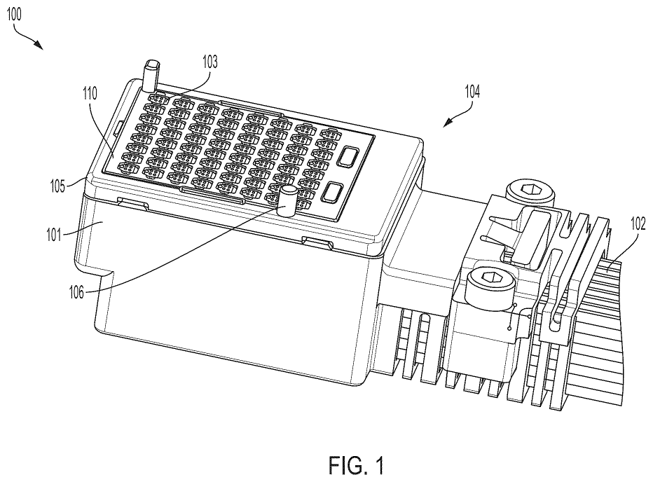

For purposes of illustration, an exemplary compliant contact array is described in connection with a pressure mount electrical connector. In the specific example of FIG. 1, the compliant contact array forms ground connections. Though, materials, shapes and techniques described herein may be applied to a compliant contact array that alternatively or additionally connects structures carrying signals.

In some examples, compliant contact arrays may be configured to allow conductors of an electrical conductor to pass therethrough. Optionally, the compliant contact arrays may have openings through which conductive beams, leads, contacts, among other conductors pass and couple to electrical components such as pads or vias of a PCB. In some examples, the openings may be sized and/or positioned to accommodate high densities of connector conductors, for example, pitches of up to 3.2×3 mm, up to 2.4×4 mm or up to 1.8×2 mm. In some examples, openings in compliant contact arrays may be substantially rectangular, substantially circular, or other suitable shapes. In some examples, one or more tabs may extend into the openings. In some examples, the openings may have one or more curved edges. In some examples, each of a plurality of openings may have dimensions of approximately 2×2 mm, 1.7×1.7 mm, 1.5×1.5 mm, 1.3×1.3 mm, 2×1.9 mm, 1.9×1.8 mm, 1.8×1.7 mm, 1.7×1.6 mm, 1.6×1.5 mm, 1.5×1.4 mm, 1.0×1.0 mm, 0.9×0.9 mm, 0.8×0.8 mm, 0.7×0.7 mm, 0.6×0.6 mm, 0.5×0.5 mm, any dimension between 0.5-2×0.5-2 mm, or any dimensions between 1.3-2×1.3-2 mm.

In some examples, differential pairs of conductors may pass through the openings of the compliant contact arrays. In some examples, compliant contact arrays may be configured to allow close spacing of differential pairs, for example, less than to 15 mm² area per differential pair, less than 12 mm² area per differential pair, less than 10 mm² area per differential pair, less than 9.5 mm² area per differential pair, less than 9 mm² area per differential pair, less than 8 mm² area per differential pair up, less than 7 mm² area per differential pair, less than 6.5 mm² area per differential pair, less than 6 mm² area per differential pair, less than 5 mm² area per differential pair for example.

An exemplary embodiment of an electrical connector 100 with a compliant contact array 110 is shown in FIG. 1. The electrical connector 100 includes housing 101, which supports a plurality of cables 102. The cables are connected to contacts 103 at mating interface 104. The contacts 103 are arranged in groups of two, however other arrangements may be used. In FIG. 1, the bottom, of connector 100 which here represents the surface mated to a PCB, is visible.

The connector 100 additionally includes compliant contact array 110, which in this example is secured to the housing 101 via retaining member 105. As shown, the compliant contact array 110 includes holes such that the groups of contacts are exposed therethrough. The compliant contact array 110 may have a conductive layer selectively applied. The conductive layer may be applied to correspond to locations of conductive features on a printed circuit board (PCB), which the connector 100 is designed to attach to. In this example the contacts 103 are configured as compliant beams such that connector 100 is configured for mating to a substrate at a pressure mount interface.

The connector 100 may connect to a PCB (not shown in FIG. 1), with mating interface 104 facing the printed circuit board. The PCB may include conductive features to connect to the contacts 103 and the compliant contact array 110. For example, the PCB may include conductive pads. Those pads may include signal pads, and each of the contacts 103 may press against a respective signal pad. The PCB may alternatively or additionally include one or more ground pads, and contact regions of the compliant contact array 110 may align with and press against the one or more ground pads.

The connector 100 may be connected to a PCB by applying a mating force to the connector. The mating force may be a pressing force, which presses the mating interface 104 towards the surface of the PCB. The mating force may compress or otherwise deform compliant contact array 110 such that the array is electrically connected to features of the PCB. Optionally, connector 100 may include guideposts 106, which fit in holes within the PCB to position connector 100 with respect to pads on the PCB. A mating force may be applied to press connector 100 towards a PCB via mechanical structures (not shown in FIG. 1).

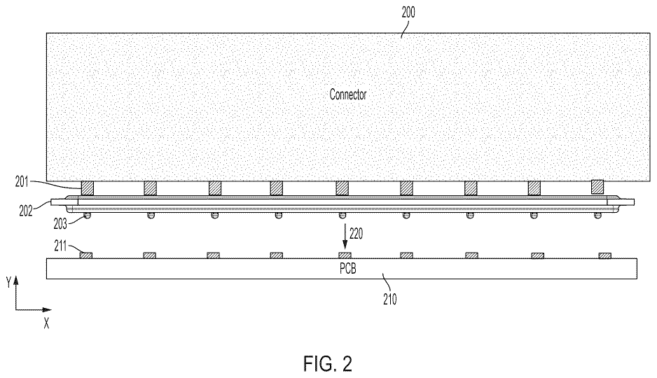

FIG. 2 is a side, schematic view of an electrical interconnection system having a compliant contact array, according to some embodiments. As shown, the connector 200 includes conductive features 201 which connect to the compliant contact array 202. In some embodiments, the conductive features 201 may be cables, cable shields, contact pins, beams, leads or other suitable electrical conductors and may be ground and/or signal structures. The conductive features may contact regions of compliant contact array 202 which have a conductive coating applied.

The compliant contact array 202 includes protrusions 203, which extend from the side of the array opposite the connector. The protrusions may be configured to electrically connect to conductive features of a PCB to which connector 200 is connected to. As shown, the protrusions are configured to connect to the conductive pads 211 on PCB 210.

In some embodiments, the protrusions 203 may compress or otherwise deform when the connector is connected to PCB 210. The connector 200 may be connected to the PCB 210 by moving the connector in direction 220 towards the PCB 210. A mating force may be applied to the connector 200 in direction 220 to electrically connect the connector 200 to the PCB 210. The protrusions may compress in response to the mating force.

The protrusions may change shape in response to the mating force. For example, the protrusions may become wider or narrower in the X direction, compress in the Y direction, fold in the X or Y direction, collapse in the X or Y direction. The protrusions may return to their original shape when the mating force is removed.

The shapes of the protrusions may be selected to give desired properties. In some embodiments, the shape of the protrusions may be selected to provide a desired level of deflection or compression in response to a specific level of force. In some embodiments, the shape of the protrusions may be selected to fold, collapse or telescope to a certain depth responsive to a specific force. In some embodiments, the shapes of the protrusions may be selected to fold or collapse multiple times.

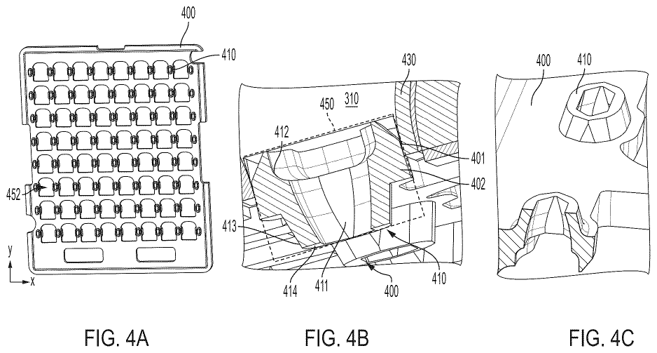

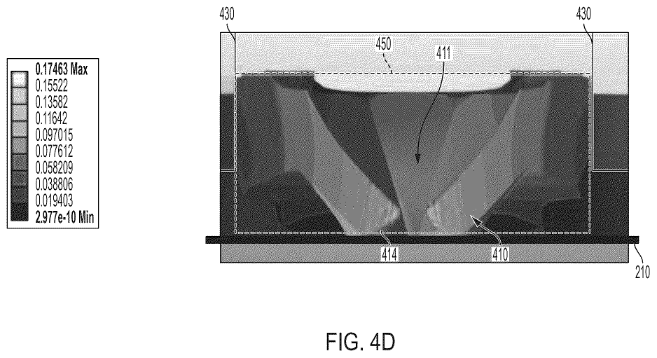

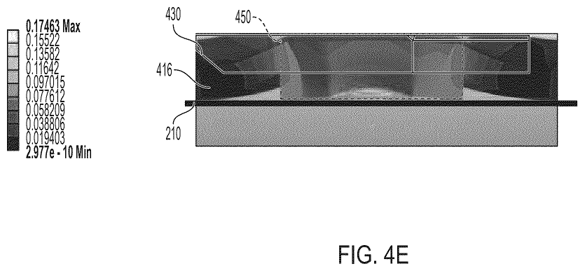

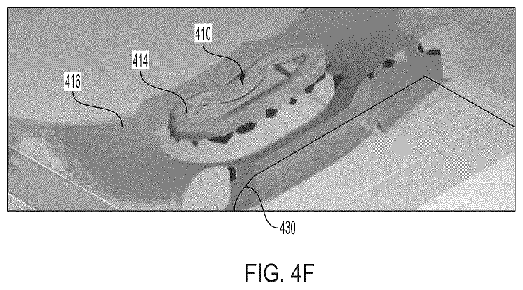

Specific shapes and arrangements of compliant contact arrays are discussed with regard to FIGS. 4A-17D.

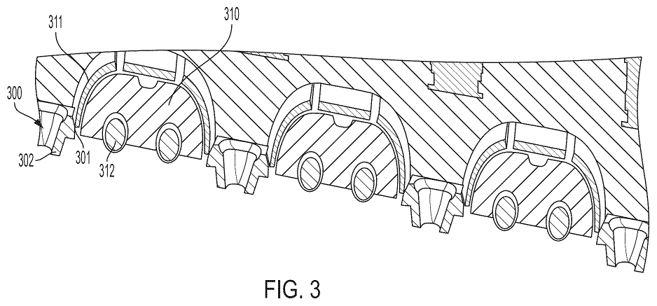

FIG. 3 is a sectional view of an electrical connector with a compliant contact array, such as connector 100 in FIG. 1. In this example, each of the cables 102 is a twin-ax cable, with a pair of conductors 312 and a surrounding ground shield. Each cable is terminated to a similar structure, such as a pair of contacts 103 (FIG. 1), which may be shaped as compliant beams that extend through the mating face of the connector. The cable ground shields are terminated to connector shields 311, which surround a module housing 310 holding the pair of contacts.

As shown, the compliant contact array 300 contacts the shields 311 at contact locations 301. As shown, the contact locations are associated with the locations of protrusions 302 of the compliant contact array 300. The compliant contact array 300 may have a conductive layer applied at the contact locations 301. The compliant contact array may provide an electrical connection between the shields 311 and a PCB or other component to which the connector is mounted.

The arrangement shown in FIG. 3 may be used to improve signaling performance of high speed signals, as the locations of the protrusions can be selected to reduce perturbations of the signal paths through the interconnection system that may degrade signal integrity.

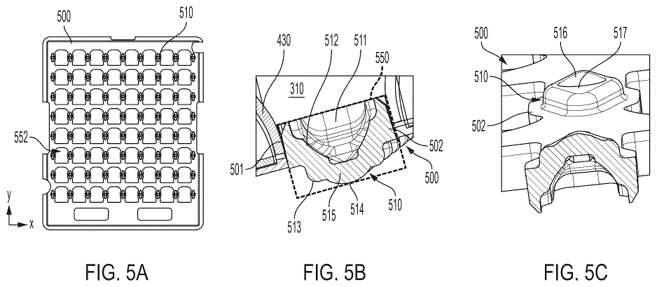

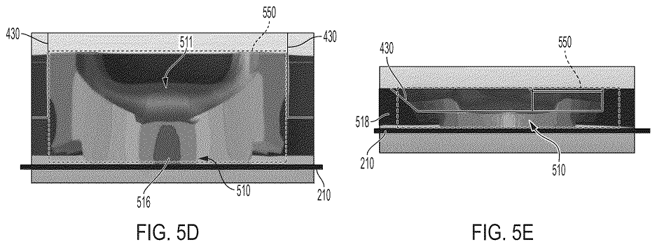

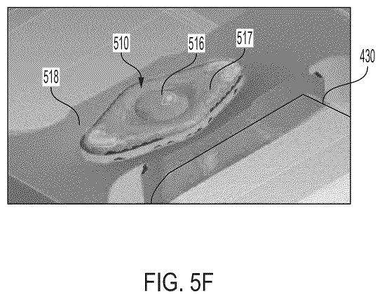

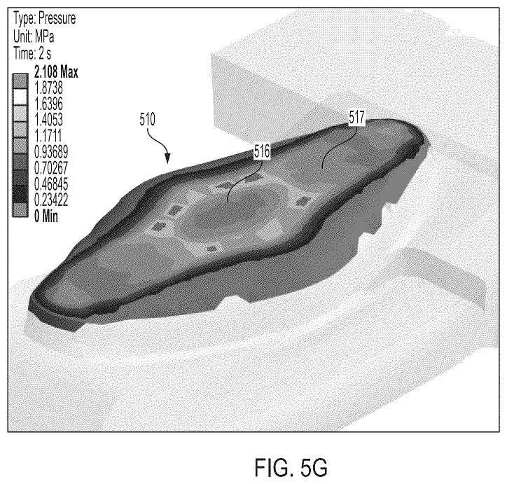

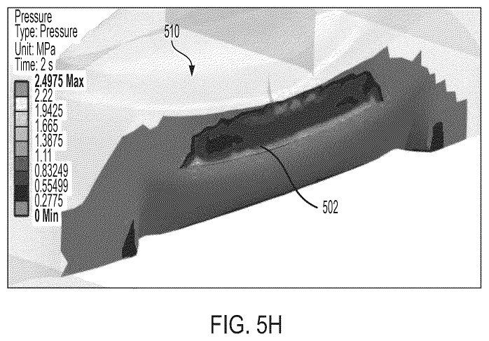

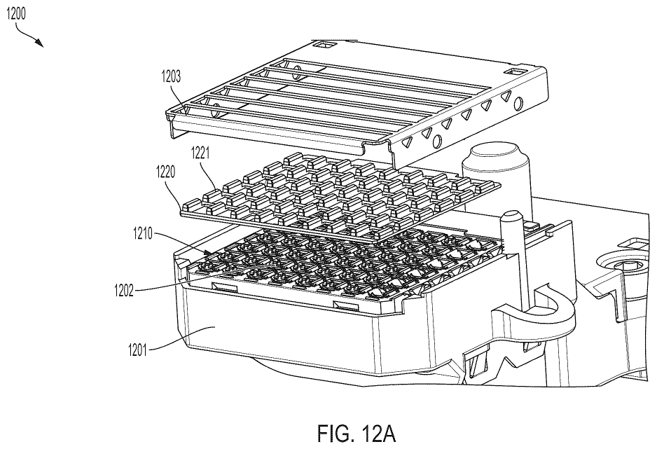

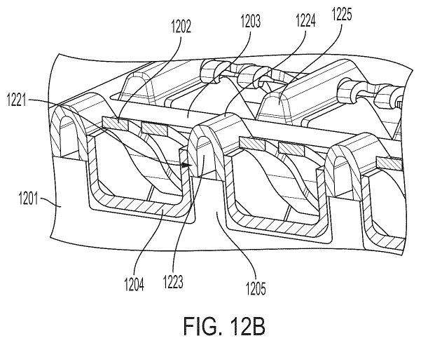

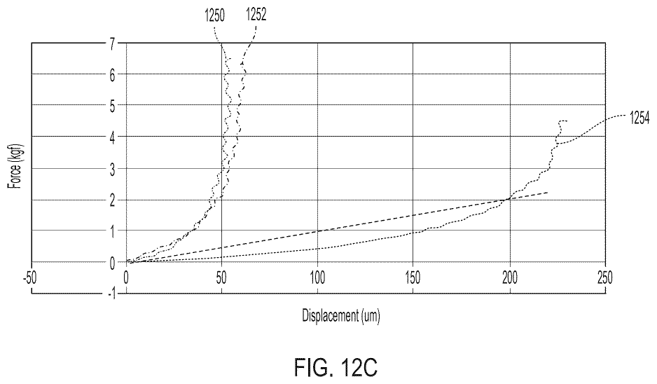

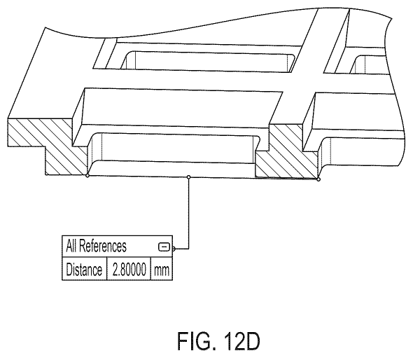

FIG. 4A is a bottom view of a compliant contact array having a plurality of protrusions, as in FIG. 3. FIGS. 5A, 6A, 7A, 8A, 9A, 10A, 11A, 13, 14, 15A, 16A, 17A, and array 1220 of FIGS. 12A-D are alternative configurations of a compliant contact array that may similarly be used in a connector as in FIG. 1. These embodiments differ in the shape of their contact regions, such that the compressive displacement and/or mating force of the compliant contact array varies for these configurations. These embodiments, however, illustrate contact arrays that may be formed using similar materials and structures that may similarly be used to make connections to or through a contact array. For simplicity of explanation, description of all of these similarities is not repeated for all embodiments.

Returning to FIG. 4A, array 400 may be attached to an electrical connector as described herein, for example, as described with reference to FIGS. 1-3. In some embodiments, array 400 may be mounted to an electrical connector via a retaining member. Array 400 may be configured to contact a PCB or other electrical component when an electrical connector is pressed against the PCB or other component. Array 400 has a plurality of protrusions 410, which may contact the PCB or other component.

As can be seen in FIG. 4A, the contact array may be generally flat, extending in a plane. Protrusions may extend from the plane towards the bottom and/or towards the top. These protrusions may form portions of the contact regions. In this example, there are a plurality of contact regions held together by a web. Both the contact regions and the web, in this example, are integrally formed, such as by molding liquid silicone rubber.

In FIG. 4B a contact region 450 is shown in cross section. Contact region 450 includes a protrusion, which is a portion of the compliant contact array of FIG. 4A, shown in FIG. 4B pressed against an electrical connector. In this figure, the contact region 450 is in contact with a conductive element 430 of the electrical connector at contact location 401. The conductive element 430 may be a shield 311, for example, or another conductive element. The conductive element of the connector, for example, may extend into opening 452 (FIG. 4A) of the contact array. The bottom surface 414 of the protrusion may contact a PCB or other component against which the connector is pressed, to provide an electrical connection between the conductive element 430 and the PCB or other component.

In this example, exterior surface 413 may be coated with a conductive material, such as may be applied as a conductive ink that is allowed to dry. When the contact array is compressed between the connector and a substrate, such as a PCB, that conductive coating may form electrically conducting paths between conductive elements 430 and conductive structures on the surface of the substrate. Optionally, interior surface 412 may alternatively or additionally be coated with conductive materials.

The exterior surface 413 of the contact region provides an overall convex shape to the lower side of the array 400 at the contact region. The exterior surface includes a flat portion parallel to a plane of the array and a tapered or curved portion extending away from the plane of the array associated with the protrusion 410. The interior surface 412 of the contact region 450 provides an overall concave shape to the upper side of the array 400 at the contact region.

In this example, contact region 450 also includes a projection on the upper portion of the array 400 for making contact with conductive components. In this example, the projection fits into a void in housing 310 between adjacent conductive elements 430. The projection has tapered exterior walls such that the distal end of the projection fits between conductive elements 430. More proximal portions of the projection are wider than the separation between adjacent conductive elements 430 such that, as the projection is pushed into the void in housing 310, those more proximal portions are pushed together by a camming force generated by interference with the conductive elements 430. That camming force provides a contact force on the side walls of the projection, which in this example is in the plane of the array.

Contact region 450 may include one or more features that set properties of the contacts of the contact array. In the illustrated example, the interior surface 412 includes a first segment and a second segment, the first segment being associated with the upper, connector side of the array and the second segment being associated with the protrusion 410 on the lower side of the array. The first segment has a smaller cross-sectional radius than the second segment and forms a bowl-like cavity in the array. A hole 411 extend through the contact region 450. As can be seen, the diameter of hole 411 is different at different locations within the contact region. The shape of the interior and exterior surfaces may be set by molding an elastic material, such as an elastomer, in a liquid state, which in turn influences mechanical parameters of the contact region, such as by providing thicker or thinner walls and or tapered surfaces.

In the example of FIG. 4B, the sidewall thickness of the array varies through the thickness of the array. The sidewall thickness is smallest at the ends of the array near the connector and the bottom surface 414 of the protrusion. The sidewall is thickest near the middle of the array.

The shape of the array and protrusions may be selected to yield specific properties for the contact regions. In some examples, the shapes of the protrusions may be selected to control the deformation of the contact region when exposed to a mating force. The sidewall thickness may be varied to increase or decrease the deformation exhibited at specific force levels. The shape of the interior and exterior surfaces of the sidewall may be selected to control the direction of deformation of the array. For example, the array 400 may deform inwards, towards the center or hole 411 when a mating force is applied to the array. The array may be configured to deform inwards to reduce the area of the array in contact with the PCB or other component.

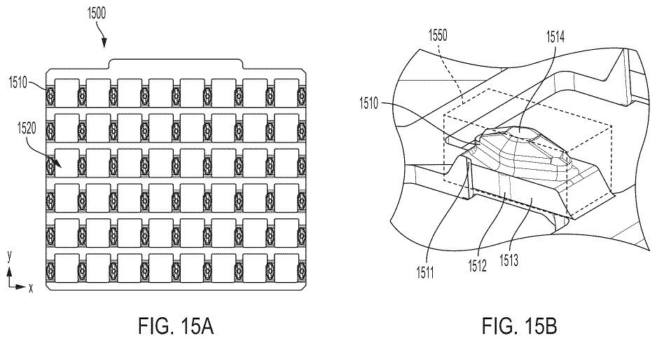

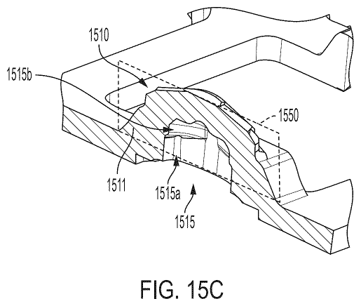

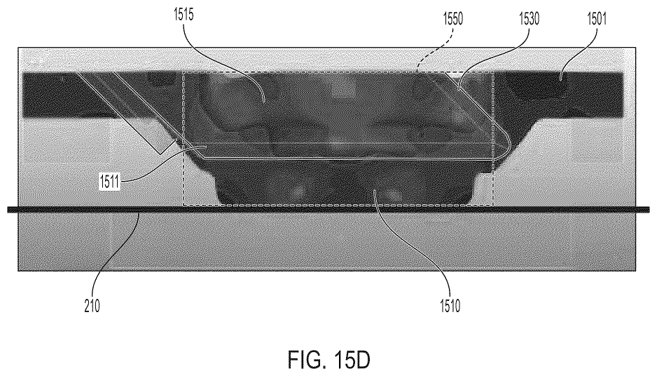

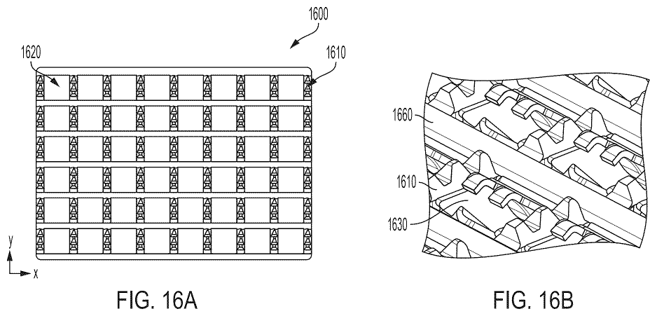

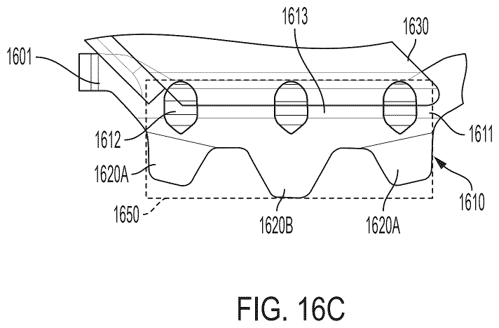

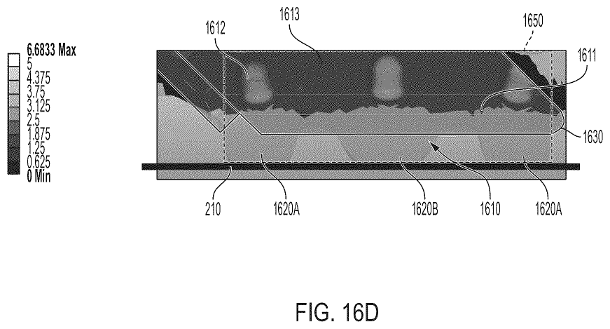

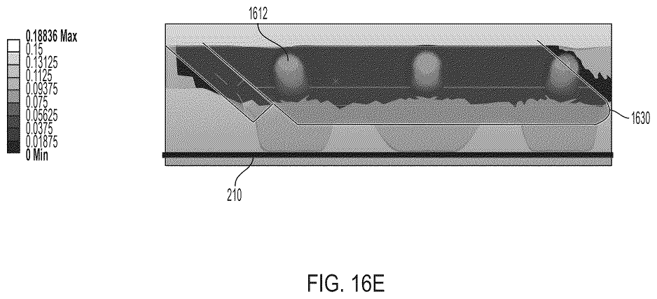

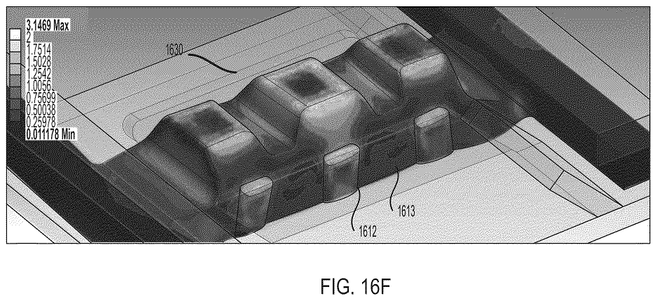

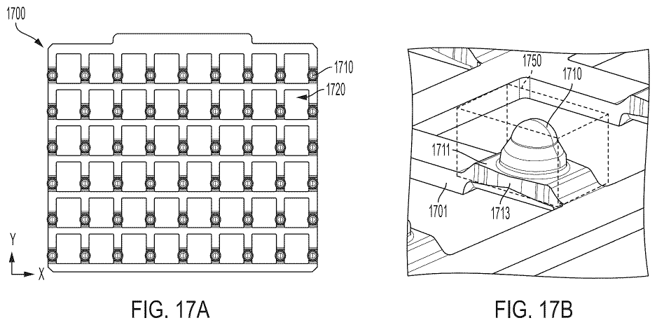

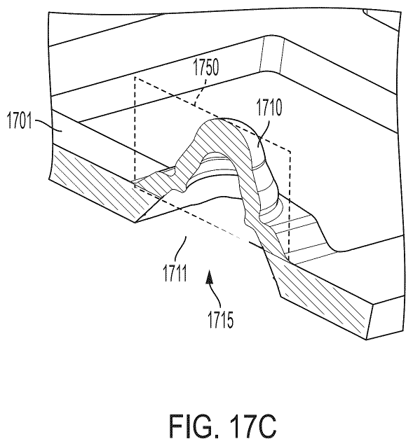

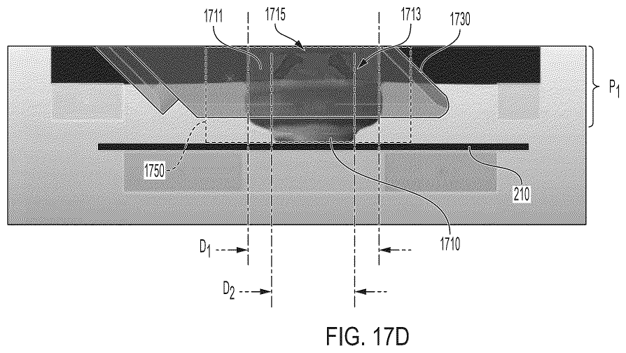

FIG. 4B additionally shows extensions 402 which are adjacent to the protrusions 410 within the contact regions of contact array 400. The extensions 402 extend outward adjacent to the protrusions 410 and are present at both sides of the protrusions 410. The extensions 402 contact the conductive elements 430 of the electrical connector. The extensions 402 may increase the contact pressure at the interface between the contact array 400 and the conductive elements 430, such as to improve the electrical connection between the contact array and the conductive elements. In some embodiments, the extensions 402 may include features for increasing the contact pressure at the interface between the contact array and the conductive elements, such as bumps (such as shown and described with reference to FIGS. 15A-16D) and/or curve outward (such as shown and described with reference to FIG. 17A-D) or other features that concentrate force in a small area. The extensions 402 may wipe along conductive elements 430 during a mating of the connector illustrated and a complimentary component, such as PCB or other substrate.

FIG. 4C is a view of a portion of the lower surface of array 400 including protrusions 410. As shown in FIG. 4C, the protrusions have an oblong shape in the plane of the array 400. The shape of the protrusions 410 may be selected to have desired deformation when the array is pressed against a PCB or other component. In this example, the sidewalls of the protrusion may, when the protrusion is subjected to a mating force, bend towards the major axis of the oblong shape, which may preclude the elastic material, and conducting coating on its exterior surfaces, from getting closer to adjacent signal conductors, which could otherwise interfere with signal integrity.

FIG. 4D is a section view of a contact region 450 of compliant contact array 400 pressed against PCB 210. The section view is taken along a direction parallel to the x-axis in FIG. 4A. As shown, the contact array is included within an electrical connector, and the connector may be mated to the PCB via a mating process that involves applying a mating force to the connector to urge the connector towards the PCB. As shown, the contact region 450 compresses between the electrical connector and the PCB 210. The portions of the contact region 450 in contact with the conductive elements 430 may wipe along the conductive elements due to the change of shape of the contact region 450 as it is compressed. Additionally, the protrusion 410 of the contact region 450 deforms responsive to the mating force and collapses inward towards hole 411. The sidewalls of the protrusion move inwards towards hole 411 and therefore the bottom surface 414 of the protrusion 410 may wipe along the PCB 210 during mating.

FIG. 4E is a section view, taken from a direction normal to the view of FIG. 4D, of the contact region 450 of contact array 400 pressed against PCB 210. The view of FIG. 4D is taken through a contact region of contact array 400 in a direction parallel to the y-axis of FIG. 4A. FIG. 4E includes a transparent outline of conductive element 430 of the electrical connector. As shown, the contact region 450 is deformed relative to the web 416 of the contact array, with the contact array bowing around the contact region which is pressed upwards towards the connector. Deformation of the contact region 450 enables the contact region to wipe along conductive elements 430 during mating.

The views of FIGS. 4D and 4E are shaded according to the displacement of the compliant contact array from the uncompressed to the compressed state. The keys, at the left of FIGS. 4D and 4E, show the displacement level (in mm) corresponding to different shadings. As shown, the protrusion 410 experienced more deformation than the other portions of the compliant contact array, with the internal edges of the sidewalls of the protrusion displaced by the greatest amount, approximately 0.175 mm. These portions of the protrusion collapsed inwards as the compliant contact array was pressed into the PCB 210. The displacement amounts of the portions of the protrusion in contact with PCB 210 and the portions of the contact region in contact with the conductive elements 430 demonstrate they have wiped along these surfaces during mating with the PCB 210.

The geometries of features of the compliant contact array may be selected to control the displacement of the contact array during mating, for example, features of the compliant contact array may be designed to deform by a specified amount at different mating forces. For example, the thickness, shape, or dimensions of protrusions, the web, and/or other features of the compliant contact array may be selected such that the compliant contact array deforms in a specific way or by a specific amount. For example, portions of a compliant contact array may be made thicker or thinner, and/or may include tapers, steps, or other features to control the displacement of the array during mating.

In the example of FIGS. 4D-E, the contact regions 450 of the compliant contact array 400 are designed to deform by collapsing inwards during mating, therefore causing the protrusions 410 to experience the largest level of displacement. As shown, the shape of the protrusions 410 in a plane parallel to the contact array, is oblong with a hexagonal hole at the bottom of the compliant contact arrays. This shape of the protrusions 410 encourages the protrusions to collapse inwards during mating. The shape may be altered to control the amount the protrusions collapse by, and therefore the displacement of the portions of the protrusion during mating. For example, the sidewalls of the protrusions 410 may be made thicker to reduce their deformation at the same mating force. Alternatively, the shapes of the protrusions in a plane parallel to the plane of the compliant contact array may be changed, such as by making the protrusions less or more oblong to reduce or increase collapse of the protrusions, respectively.

A similar principle will apply to the other compliant contact arrays described herein, including the compliant contact arrays of FIGS. 5A-17D. That is, the features of the compliant contact array may be selected to control the amount of deformation experienced during mating of the compliant contact array.

FIG. 4F is a view of a protrusion 410 of compliant contact array in a compressed state. The protrusion 410, as shown in FIG. 4F may be compressed such as would occur when a connector is mated to a PCB (e.g., by applying a mating force to an electrical connector including the contact array). As shown, the protrusion 410 is in a compressed state with the sidewalls collapsing inwards. The bottom surface 414 of the protrusion 410 flattens, such as occurs from being urged against a PCB. Additionally, FIG. 4F shows the web 416 and portions of the contact region of the contact array bowing around the protrusion 410. As discussed above, this bowing around the protrusion 410 enables the contact region of the contact array to wipe along the conductive element 430. A transparent outline of conductive element 430 is shown in FIG. 4F.

FIG. 5A is a bottom view of a compliant contact array having a plurality of contact regions, according to some embodiments. Array 500 may be attached to an electrical connector as described herein, for example, as described with reference to FIGS. 1-3. In some embodiments, array 500 may be mounted to an electrical connector via a retaining member. Array 500 may be configured to contact a PCB or other electrical component when an electrical connector is connected the PCB or other component. Array 500 has a plurality of protrusions 510, which may contact the PCB or other component when the connector is pressed against that component.

FIG. 5B is a sectional view of a contact region of the compliant contact array of FIG. 5A pressed against an electrical connector. As shown, contact region 550 has a projection shaped similarly to the projection in the contact region of FIG. 4B. The projection similarly makes contact with a conductive element 430 of the electrical connector at contact location 501. The conductive element of the connector, for example, may extend into opening 552 (FIG. 5A) of the contact array. The size and/or shape of the projection, including the size of the opening in it and/or the thickness of the walls may differ from that shown in FIG. 4B to provide a higher or lower contact pressure at contact locations 501.

FIG. 5B shows that the contact region has a protrusion in the lower surface of the contact array that may have less variation in the width of the contact region when compressed. In this example, the protrusion has a distal tip portion, here shown as a raised bump, that may telescope into a more proximal portion when compressed. The width of the protrusion may be, throughout compression, influenced by the width of the more proximal portion into which the more distal portions telescope.

In this example, exterior surface 513 may be coated with a conductive material, such as may be applied with a conductive ink that is allowed to dry. When the contact array is compressed between the connector and a substrate, such as a PCB, that conductive coating may form electrically conducting paths between conductive elements 430 and conductive structures on the surface of the substrate. In this example, interior surface 512 is not coated with a conductive material, as doing so would not provide a conductive path between the conductive elements and the substrate.

The exterior surface 513 of the cross section of the array has an overall convex shape. The exterior surface has a stepped shape associated with the protrusion, including a first step which forms membrane 515 and a second step which includes a raised bump. The membrane supports the raised bump, and the raised bump includes bottom surface 514. The thickness of the membrane and height of the raised bump may be varied to have desired properties, for example different levels of compression or deformation in response to specific forces.

The interior surface 512 of the cross section of the array 500 has an overall concave shape. The interior surface 512 includes multiple segments, with varying radii. The segments are connected to form a cavity on the connector side of the array 500. The shape of the segments of the interior and exterior surfaces may be configured for desired deformation, compression and electrical performance, as described herein.

In some embodiments, the protrusion 510 may be configured to collapse in response to a mating force. The protrusion may collapse into cavity 511 due to a mating force, providing a telescoping action. The protrusion may be configured, such as through the use of an elastic material, to return to its original shape when the mating force is removed.

FIG. 5B additionally shows extensions 502 which are adjacent to the protrusions 510 within the contact regions of contact array 500. The extensions 502 extend outward adjacent to the protrusions 510 to contact the conductive elements 430 of the electrical connector. The extensions 502 may increase the contact pressure at the interface between the contact array 500 and the conductive elements 430. In some embodiments, the extensions 502 may include features for increasing the contact pressure at the interface between the contact array and the conductive elements, such as bumps and/or curve outward, as described herein. The extensions 502 may wipe along conductive elements 430 during a mating process.

FIG. 5C is a view of the lower surface of array 500 including protrusions 510. As shown in FIG. 5C, the protrusions have rhombus shape with an inflection point between the protrusion and the array surface. The inflection point creates a location at which the walls will fold upon themselves when compressed. The protrusions include membrane surface 517 and raised bump 516 extending from the membrane surface. In some embodiments, the raised bump may contact a PCB or other electrical component. In some embodiments, the membrane surface may contact a PCB or other electrical component. The shape of the protrusions 510 may be selected to match the shapes of conductive pads of a PCB or component to which the array connects. The shape of the protrusions 510 may be selected to have desired deformation when the array is connected to a PCB or other component.

FIG. 5D is a section view of a contact region 550 of compliant contact array 500 pressed against PCB 210. The section view is taken along a direction parallel to the x-axis in FIG. 5A. As shown, the contact array is included within an electrical connector, and the connector may be mated to the PCB via a mating process such as described herein. As shown, the contact region 550 compresses between the electrical connector and the PCB 210. The portions of the contact region 550 in contact with the conductive elements 430 may wipe along the conductive elements 430 due to the change of shape of contact region 550 as it is compressed. As shown, the contact region 550 adjacent to the conductive elements 430 is deformed and bows due to the contact with the PCB 210. Additionally, the bump 516 on protrusion 510 is flattened from contact with the PCB 210, and the protrusion deforms and collapses inward into cavity 511.

FIG. 5E is a section view, taken from a direction normal to the view of FIG. 5D, of the contact region 550 of contact array 500 pressed against PCB 210. The view of FIG. 5D is taken through a contact region of contact array 500 in a direction parallel to the y-axis of FIG. 5A. FIG. 5E includes a transparent outline of conductive element 430 of the electrical connector. As shown, the contact region 550 is deformed relative to the web 518 of the contact array, with the contact array bowing around the contact region which is pressed upwards towards the connector. Deformation of the contact region 550 enables the contact region to wipe along conductive elements 430 during mating.

FIG. 5F is a view of a protrusion 510 of compliant contact array in a compressed state. The protrusion 510, as shown in FIG. 5F, may be compressed such as would occur when a connector is mated to a PCB. As shown, the protrusion 510 is in a compressed state with the bump 516 flattening and the membrane surface 517 bowing around the bump 516. Portions of the membrane surface 517 additionally flatten, such as would occur from being urged against a PCB. Additionally, FIG. 5F shows the web 518 and portions of the contact region of the contact array bowing around the protrusion 510. This bowing around the protrusion 510 enables the contact region of the contact array to wipe along the conductive element 430, shown as a transparent outline in FIG. 5F.

FIG. 5G is a view of a protrusion of 510 of a compliant contact array in a compressed state and shaded according to the pressure at the bottom surface of the compliant contact array. The pressures shown in FIG. 5G represent the pressures at the interface between the protrusion 510 and a substrate (e.g., a pad of a PCB). The key at the left of FIG. 5G includes the shading and corresponding pressure levels in MPa of the protrusion. As shown, the protrusion 510 has the highest pressure on the membrane surface 517 surrounding the bump 516 of between about 1.405-2.108 MPa. This is due to the shape of the protrusion and how it deforms during mating. During mating the bump 516 is compressed into the compliant contact array, causing the portions of the membrane surface 517 surrounding the bump to press into the substrate at higher pressures. There are additional areas of high pressure at the ends of the protrusions, along the y direction in FIG. 5A.

FIG. 5H is a view of the side a protrusion of 510 of a compliant contact array in a compressed state and shaded according to the contact pressure against a conductive element of an electrical connector. The pressures shown in FIG. 5H represent the pressures at the interface between the extensions 502 of the compliant contact array and the conductive element 430 (e.g., a shield of an electrical connector). The key at the left of FIG. 5H includes the shading and corresponding pressure levels in MPa of the extension. As shown, the extension 502 has the highest pressure at the top and bottom edges of the area of contact with the conductive element of about 1.3875-2.4975 MPa. This is due to the deformation of the compliant contact array during mating, where the protrusions are pressed up, in toward the shields and the extensions adjacent to the protrusions press against the shields.

The geometries of features of the compliant contact array 500 may be selected to control the pressures generated during mating at the interface between the compliant contact array and a substrate (e.g., a pad of a PCB) and at the interface between the compliant contact array and a conductive element (e.g., a shield of an electrical connector). For example, features of the compliant contact array may be designed to increase the pressure and/or to increase the area of the compliant contact arrays with high pressure contact at the interfaces between the compliant contact array and the substrate and/or conductive elements of a connector. Increasing the contact pressure and/or the area of compliant contact arrays with high contact pressure will improve the electrical connection between the compliant contact array and the substrate and/or conductive elements of a connector. In the example of FIG. 5G, the position, size, thickness and/or shape of the bump 516 may be selected to increase the pressure or area of high pressure on the protrusion during mating. Additionally, or alternatively, one or more additional bumps may be included on the membrane surface 517 to increase the pressure and/or area of high pressure at the interface of the compliant contact array with the substrate. In the example of FIG. 5H, the extensions may protrude further away from the protrusions, may have different shapes (e.g., may curve outward), and/or may include features (e.g., bumps such as bumps 1612 of FIG. 16C), which increase the pressure and/or area of high pressure at the interface between the compliant contact array and the conductive elements of an electrical connector.

A similar principle will apply to the other compliant contact arrays described herein, including the compliant contact arrays of FIGS. 4A-17D. That is, the features of the compliant contact array may be selected to control the pressures at interfaces between a compliant contact array and a substrate (e.g., pads of a PCB) and/or conductive elements of an electrical connector (e.g., shields of an electrical connector) generated during mating of the compliant contact array.

FIG. 5I is a view of a contact region 550 of a compliant contact array, in a compressed state and shaded according to the elastic strain within the protrusion. The key at the left of FIG. 5I includes the shading and corresponding elastic strain levels in mm/mm within the compliant contact array. It should be noted the contact region 550 in the example of FIG. 5I includes a bump along the center of extension 502. As shown, the areas with the highest elastic strain on the protrusion 510 correspond to the areas of high contact pressures in FIG. 5G, including the areas surrounding the bump 516 and at the ends of the protrusion. The elastic strain in these areas within the protrusion ranges from about 0.15051 to 0.71677 mm/mm. The bump running vertically along the extension additionally has high elastic strain. The geometries of features of the compliant contact array may be selected to increase the elastic strain generated at different areas, for example to yield greater contact pressures at these areas during mating. Increasing the strain generated during mating at specific areas will help ensure a stable electrical connection is formed between the compliant contact array and a substrate (e.g., conductive pads of a PCB), and/or conductive elements of a connector.

A similar principle will apply to the other compliant contact arrays described herein, including the compliant contact arrays of FIGS. 4A-17D. That is, the features of the compliant contact array may be selected to control the elastic strain generated within a compliant contact array during mating of the compliant contact array.

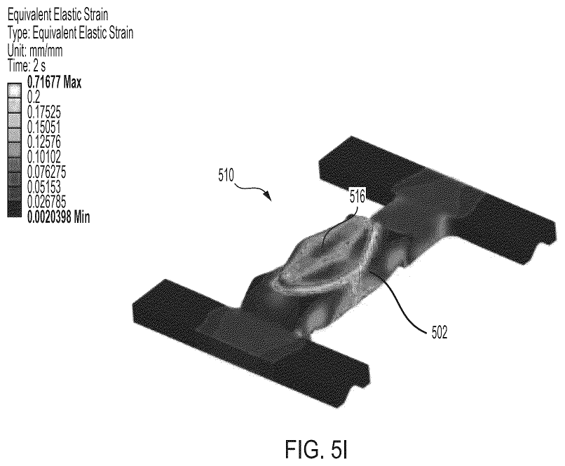

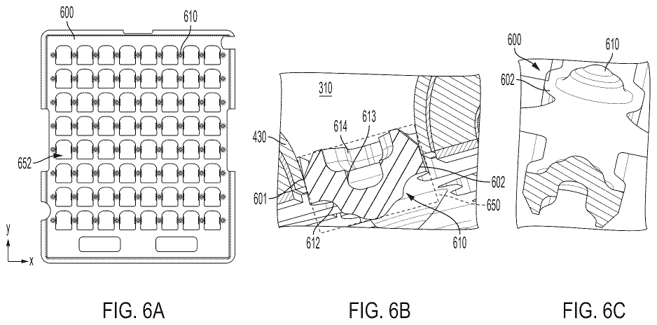

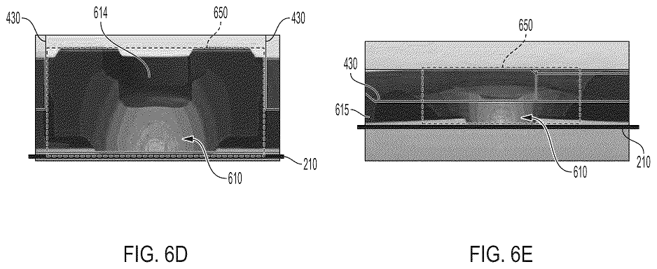

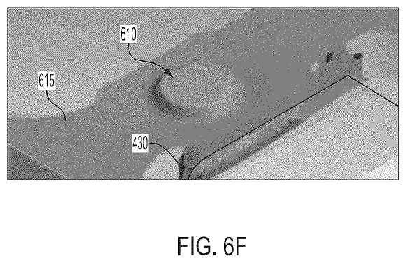

FIG. 6A is a bottom view of a compliant contact array having a plurality of protrusions, according to some embodiments. Array 600 may be attached to an electrical connector as described herein, for example, as described with reference to FIGS. 1-3. In some embodiments, array 600 may be mounted to an electrical connector via a retaining member. Array 600 may be configured to contact a PCB or other electrical component when an electrical connector is connected the PCB or other component. Array 600 has a plurality of protrusions 610, which may contact the PCB or other component when the connector is pressed against that component.

FIG. 6B is a sectional view of a contact region of the compliant contact array of FIG. 6A pressed against an electrical connector. As shown, contact region 650 has a projection shaped similarly to the projection in the contact region of FIG. 4B. The projection similarly makes contact with a conductive element 430 of the electrical connector at contact location 601. The conductive element of the connector, for example, may extend into opening 652 (FIG. 6A) of the contact array. The size and/or shape of the projection, including the size of the opening in it and/or the thickness of the walls may differ from that shown in FIG. 4B to provide a higher or lower contact pressure at contact locations 601.

FIG. 6B shows that the contact region has a protrusion in the lower surface of the contact array that is configured to minimize variation in the width of the contact region when compressed. In this example, the protrusion has a distal tip portion, here shown as a raised bump, and multiple inflection points, such that the protrusion may telescope into a when compressed.

In this example, exterior surface 612 may be coated with a conductive material, such as may be applied with a conductive ink that is allowed to dry. When the contact array is compressed between the connector and a substrate, such as a PCB, that conductive coating may form electrically conducting paths between conductive elements 430 and conductive structures on the surface of the substrate. In this example, interior surface 613 is not coated with a conductive material, as doing so would not provide a conductive path between the conductive elements and the substrate.

The exterior surface 612 of the contact region has an overall convex shape. The exterior surface includes a first step and a second step. These steps have inflection points which may allow the protrusion to telescope under compression.

The interior surface 613 of the contact region 650 has an overall concave shape. The interior surface 613 includes multiple segments, with different radii. The segments are connected to form a cavity 614 on the connector side of the array 600. The inflection points of the segments of the interior surface 613 may facilitate a collapsing or telescoping of the protrusion 610 responsive to a mating force. The shape of the segments of the interior and exterior edges may be configured for desired deformation, compression and electrical performance, as described herein.

In some embodiments, the protrusion 610 may be configured to collapse in response to a mating force. The protrusion may collapse into cavity 614 due to a mating force, providing a telescoping action. In some embodiments, the steps of the protrusion may collapse individually in response to different applied forces. The size of the steps of the protrusion, sidewall thickness, radii of the surfaces of the protrusion, and the relative sizes of the features of the protrusion may be selected to provide desired properties. The protrusion may be configured, such as through the use of an elastic material, to return to its original shape when the mating force is removed.

FIG. 6B additionally shows extensions 602 which are adjacent to the protrusions 610 within the contact regions of contact array 600. The extensions 602 extend outward adjacent to the protrusions 610 to contact the conductive elements 430 of the electrical connector. The extensions 602 may increase the contact pressure at the interface between the contact array 600 and the conductive elements 430. In some embodiments, the extensions 602 may include features for increasing the contact pressure at the interface between the contact array and the conductive elements, such as bumps and/or curve outward, as described herein. The extensions 602 may wipe along conductive elements 430 during a mating process.

FIG. 6C is a view of the surface of array 600 including protrusions 610. As shown in FIG. 6C, the protrusions a circular shape, with multiple steps corresponding to the exterior cross sectional shape. The steps have concave radii. The protrusions 610 have dome shapes at their ends which contact PCBs or other components. The shape of the protrusions 610 may be selected to match the shapes of conductive pads of a PCB or component to which the array connects. The shape of the protrusions 610 may be selected to have desired deformation when the array is connected to a PCB or other component.

FIG. 6D is a section view of a contact region 650 of compliant contact array 600 pressed against PCB 210. The section view is taken along a direction parallel to the x-axis in FIG. 6A. As shown, the contact array is included within an electrical connector, and the connector may be mated to the PCB via a mating process such as described herein. As shown, the contact region 650 compresses between the electrical connector and the PCB 210. The portions of the contact region 650 in contact with the conductive elements 430 may wipe along the conductive elements 430 due to the change of shape of the contact region 650 as it is compressed. Protrusion 610 has flattened against the PCB 210, and deformed by compressing the steps and collapsing into cavity 614.

FIG. 6E is a section view, taken from a direction normal to the view of FIG. 6D, of the contact region 650 of contact array 600 pressed against PCB 210. The view of FIG. 6D is taken through a contact region of contact array 600 in a direction parallel to the y-axis of FIG. 6A. FIG. 6E includes a transparent outline of conductive element 430 of the electrical connector. As shown, the contact region 650 is deformed relative to the web 615 of the contact array, with the contact array bowing around the contact region which is pressed upwards towards the connector. Deformation of the contact region 650 enables the contact region to wipe along conductive elements 430 during mating.

FIG. 6F is a view of a protrusion 610 of compliant contact array in a compressed state. The protrusion 610, as shown in FIG. 6F may be compressed such as would occur when a connector is mated to a PCB. As shown, the protrusion 610 is compressed and the steps of the protrusion 610 have been flattened. Additionally, FIG. 6F shows the web 615 and portions of the contact region of the contact array bowing around the protrusion 610. This bowing around the protrusion 610 enables the contact region of the contact array to wipe along the conductive element 430, shown as a transparent outline in FIG. 6F.

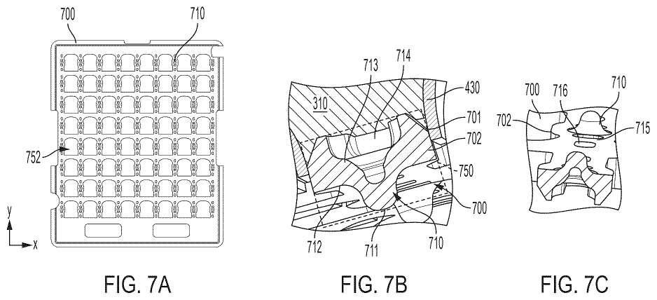

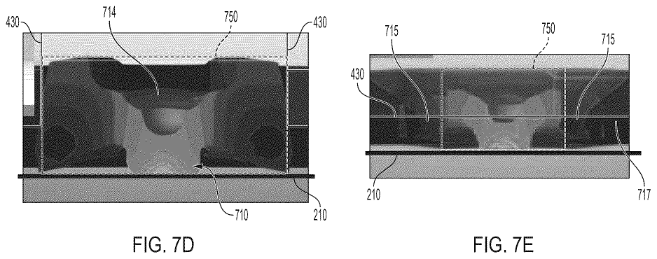

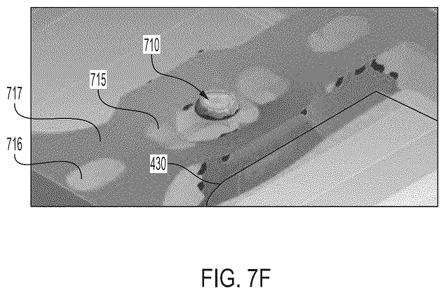

FIG. 7A is a bottom view of a compliant contact array having a plurality of contact regions, according to some embodiments. Array 700 may be attached to an electrical connector as described herein, for example, as described with reference to FIGS. 1-3. In some embodiments, array 700 may be mounted to an electrical connector via a retaining member. Array 700 may be configured to contact a PCB or other electrical component when an electrical connector is connected the PCB or other component. Array 700 has a plurality of protrusions 710, which may contact the PCB or other component when the connector is pressed against that component.

FIG. 7B is a sectional view of a contact region of the compliant contact array of FIG. 7A pressed against an electrical connector. As shown, contact region 750 has a projection shaped similarly to the projection in the contact region of FIG. 4B. The projection similarly contacts a conductive element 430 of the electrical connector at contact location 701. The conductive element of the connector, for example, may extend into opening 752 (FIG. 7A) of the contact array. The size and/or shape of the projection, including the size of the opening in it and/or the thickness of the walls may differ from that shown in FIG. 4B to provide a higher or lower contact pressure at contact locations 701.

In this example, exterior surface 712 may be coated with a conductive material, such as may be applied with a conductive ink that is allowed to dry. When the contact array is compressed between the connector and a substrate, such as a PCB, that conductive coating may form electrically conducting paths between conductive elements 430 and conductive structures on the surface of the substrate. In this example, interior surface 713 is not coated with a conductive material, as doing so would not provide a conductive path between the conductive elements and the substrate.

The exterior surface 712 of the contact region 750 of the array provides an overall convex shape to the lower side of the array 700 at the contact region. The exterior surface includes a dome shaped end. The dome includes bottom surface 711.

The interior surface 713 of the contact region of the array 700 provides an overall concave shape to the upper side of the array at the contact region. The interior surface 713 includes multiple segments, with varying radii. The segments are connected to form a cavity 714 on the connector side of the array 700. The shape of the segments of the interior and exterior edges may be configured for desired deformation, compression and electrical performance, as described herein. In some embodiments, the protrusion 710 may be configured to collapse or telescope with the distal end of the contact region pushed toward or into cavity 714 in response to a mating force.

FIG. 7B additionally shows extensions 702 which are adjacent to the protrusions 710 within the contact regions of contact array 700. The extensions 702 extend outward adjacent to the protrusions 710 to contact the conductive elements 430 of the electrical connector. The extensions 702 may increase the contact pressure at the interface between the contact array 700 and the conductive elements 430. In some embodiments, the extensions 702 may include features for increasing the contact pressure at the interface between the contact array and the conductive elements, such as bumps and/or curve outward, as described herein. The extensions 702 may wipe along conductive elements 430 during a mating process.

FIG. 7C is a view of the surface of array 700 including protrusions 710. As shown in FIG. 7C, the protrusions have a circular shape. The shape of the protrusions 710 may be selected to have desired deformation when the array is connected to a PCB or other component.

The array 700 additionally includes holes 715 and 716. The holes 715 are formed adjacent to the protrusions 710. The holes 715 have oblong shapes extending in a first direction. The holes 716 are adjacent to holes 715. The holes 716 have oblong shapes extending in a second direction perpendicular to the first direction. The holes 715 and 716 may function to control the deformation of the array 700 from a mating force. The material of the array may be configured to displace towards the insides of the holes 715 and 716, resulting from protrusions 710 pressing against a component. This may allow for greater deformation of the protrusions 710 towards the connector side of the array, while maintaining a near constant footprint for the array. In some embodiments, the holes 715 and 716 may be provided for improved electrical performance. The shapes and sizes of the holes 715 and 716 may be adjusted to provide desired properties, for example, desired compression or deformation at a specific mating force.

FIG. 7D is a section view of a contact region 750 of compliant contact array 700 pressed against PCB 210. The section view is taken along a direction parallel to the x-axis in FIG. 7A. As shown, the contact array is included within an electrical connector, and the connector may be mated to the PCB via a mating process such as described herein. As shown, the contact region 750 compresses between the electrical connector and the PCB 210. The portions of the contact region 750 in contact with the conductive elements 430 may wipe along the conductive elements 430 due to the change of shape of the contact region 750 as it is compressed. As shown, the contact region bows around the protrusion 710 and the portions adjacent the conductive elements 430 are compressed. Further, protrusion 710 has flattened against the PCB 210 and deformed by and collapsing into cavity 714.

FIG. 7E is a section view, taken from a direction normal to the view of FIG. 7D, of the contact region 750 of contact array 700 pressed against PCB 210. The view of FIG. 7D is taken through a contact region of contact array 700 in a direction parallel to the y-axis of FIG. 7A. FIG. 7E includes a transparent outline of conductive element 430 of the electrical connector. As shown, the contact region 650 is deformed relative to the web 717 of the contact array, with the contact region being pressed up towards the top of the page relative to the web in FIG. 7E. This is in part due to holes 715, adjacent to the protrusion 710, which increase the compliance of the contact array at the protrusions. This allows for greater control of the forces required to deform the contact array 700 and tailoring of the amount of travel the contact array 700 has during mating.

FIG. 7F is a view of a protrusion 710 of compliant contact array in a compressed state. The protrusion 710, as shown in FIG. 7F may be compressed such as would occur when a connector is mated to a PCB. As shown, the protrusion 710 is compressed and its surface has flattened. Additionally, FIG. 7F shows the web 717 and portions of the contact region of the contact array bowing around the protrusion 710. The holes 715 and 716 increase the deformation of the web surrounding the protrusion, and, as shown, the holes 715 and 716 are stretched due to this deformation. This bowing around the protrusion 710 enables the contact region of the contact array to wipe along the conductive element 430, shown as a transparent outline in FIG. 7F.

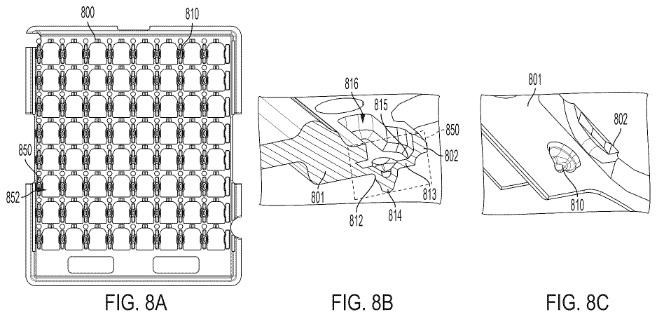

FIG. 8A is a bottom view of a compliant contact array having a plurality of contact regions, according to some embodiments. Array 800 may be attached to an electrical connector as described herein, for example, as described with reference to FIGS. 1-3. In some embodiments, array 800 may be mounted to an electrical connector via a retaining member. Array 800 may be configured to contact a PCB or other electrical component when an electrical connector is connected the PCB or other component. Array 800 has a plurality of protrusions 810, which may contact the PCB or other component when the connector is pressed against that component.

FIG. 8B is a sectional view of a contact region of the compliant contact array of FIG. 8A. As shown, contact region 850 has a projection and a lower protrusion. The contact region 850 is positioned at an edge of array 800 and therefore may only contact a conductive element on the connector side of the array at one side of the contact region. Other contact regions of the array 800 may contact multiple conductive elements of a connector, such as shown in FIG. 4B. As shown, in the orientation of FIG. 8A, the right side of the contact region has a projection shaped similarly to the projection in the contact region of FIG. 4B. The projection may similarly make contact with a conductive element of an electrical connector at a contact location. The size and/or shape of the projection, including the size of the opening in it and/or the thickness of the walls may differ from that shown in FIG. 4B to provide a higher or lower contact pressure at contact locations.

In this example, exterior surface 812 may be coated with a conductive material, such as may be applied with a conductive ink that is allowed to dry. When the contact array is compressed between the connector and a substrate, such as a PCB, that conductive coating may form electrically conducting paths between conductive elements and conductive structures on the surface of the substrate. In this example, interior surface 815 is not coated with a conductive material, as doing so would not provide a conductive path between the connector and conductive structures on the surface of the substrate.

The exterior surface 812 of the contact region 850 provides an overall convex shape to the lower side of the array 800 at the contact region. The exterior surface includes multiple steps, formed by inflection points in the surface. The protrusion includes a membrane 813, which has a bump 814 extending therefrom. The bump 814 has a concave interior and a convex exterior. The thickness of the membrane 813 and bump 814 may be tailored to have specific properties, such as deformation or electrical performance.

The interior surface 815 of the contact region of array 800 provides an overall concave shape to the connector side of the array. The interior surface 815 includes multiple segments. The segments are connected to form a cavity 816 on the connector side of the array 800. The segments of the array are associated with the upper and lower protrusions of the contact region 850. The segments associated with the projection form a straight sidewall with a chamfer. The segments additionally include segments forming the membrane and interior surfaces of the protrusion. The shape of the segments of the interior and exterior edges may be configured for desired deformation, compression and electrical performance, as described herein.

In some embodiments, the protrusion 810 may be configured to collapse or telescope into cavity 816 in response to a mating force. The protrusion may be configured, for example through use of an elastic material, to return to its original shape when the mating force is removed.

FIG. 8B additionally shows extensions 802 which are adjacent to the protrusions 810 within the contact regions of contact array 800. The extensions 802 extend outward adjacent to the protrusions 810, such as to contact conductive elements (e.g., conductive shields) of an electrical connector which the contact array 800 is coupled to. The conductive element of the connector, for example, may extend into opening 852 (FIG. 8A) of the contact array. As shown in FIG. 8C, the extensions 802 curve outward from the web 801 of the contact array to increase the contact pressure at the interface between the contact array 800 and conductive elements. In some embodiments, the extensions 802 may include further features for increasing the contact pressure at the interface between the contact array and the conductive elements, such as bumps, as described herein. The extensions 802 may wipe along conductive elements during a mating process.

FIG. 8C is a view of the lower surface of array 800 including protrusions 810. As shown in FIG. 8C, the protrusions have an oblong shape in the plane of the array 800. The protrusions 810 have dome shapes at their ends which may contact PCBs or other conductive elements. The shape of the protrusions 810 may be selected to have desired deformation when the array is connected to a PCB or other component.

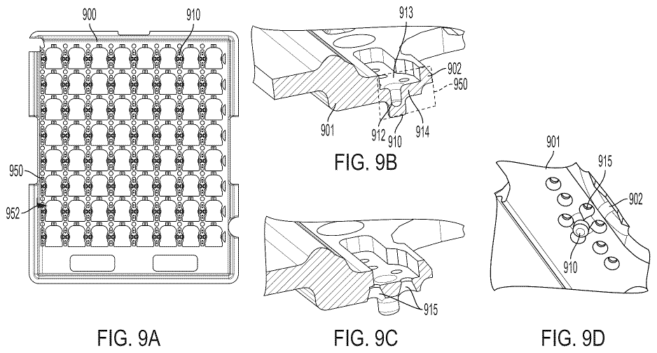

FIG. 9A is a bottom view of a compliant contact array having a plurality of contact regions, according to some embodiments. Array 900 may be attached to an electrical connector as described herein, for example, as described with reference to FIGS. 1-3. In some embodiments, array 900 may be mounted to an electrical connector via a retaining member. Array 900 may be configured to contact a PCB or other electrical component when an electrical connector is connected the PCB or other component. Array 900 has a plurality of protrusions 910, which may contact the PCB or other component when the connector is pressed against that component.

FIG. 9B is a sectional view through a contact region of the compliant contact array of FIG. 9A. The contact region includes a protrusion which may be a protrusion of the array 900.

As shown, contact region 950 has a projection and a lower protrusion. The contact region 950 is positioned at an edge of array 900 and therefore may only contact a conductive element on the connector side of the array at one side of the contact region. Other contact regions of the array 900 may contact multiple conductive elements of a connector, such as shown in FIG. 4B. The conductive element of the connector, for example, may extend into opening 952 (FIG. 9A) of the contact array. As shown, the right side of the contact region 950 in the orientation of FIG. 9A has a projection shaped similarly to the projection in the contact region of FIG. 4B. The projection may similarly make contact with a conductive element of an electrical connector at a contact location. The size and/or shape of the projection, including the size of the opening in it and/or the thickness of the walls may differ from that shown in FIG. 4B to provide a higher or lower contact pressure at contact locations.

The exterior surface 912 of the contact region of the array provides an overall convex shape to the lower side of the array at the contact region. The exterior surface includes a depression 913 and membrane 914 between the depression and the protrusion 910. The protrusion 910 has a concave interior edge and has a cavity therein which joins with the depression 913. The thickness of the membrane 914 and of the protrusion sidewall may be tailored to have specific properties, such as deformation or electrical performance.

In this example, exterior surface 912 may be coated with a conductive material, such as may be applied with a conductive ink that is allowed to dry. When the contact array is compressed between the connector and a substrate, such as a PCB, that conductive coating may form electrically conducting paths between conductive elements and conductive structures on the surface of the substrate. In this example, interior surface is not coated with a conductive material, as doing so would not provide a conductive path between the connector and conductive structures on the surface of the substrate.

In some embodiments, the protrusion 910 may be configured to collapse in response to a mating force. The protrusion may collapse into the depression 913 due to a mating force. The protrusion may be configured, for example through the use of an elastic material, to return to its original shape when the mating force is removed.

FIG. 9C is a sectional view of a portion of a membrane of the array of FIG. 9A. The view of FIG. 9C is taken through two holes 915 which are formed in the membrane 914. As shown, the membrane 914 has multiple holes therethrough. The holes extend from a surface of the array on the same side as the protrusion 910 to the depression 913. As shown, the holes 915 are countersunk holes, with a tapered portion and a straight portion. The tapered portion opens towards the side of the array with the protrusions, and tapers from a first diameter to a second diameter, smaller than the first. The straight portion has the second diameter. The shapes and arrangements of the holes may be varied to have desired properties, including to control the compression or deformation of the protrusion or for improved electrical connections.

The holes 915 may allow for the material of the array to displace responsive to a mating force. For example, material adjacent the holes and protrusion 910 may move towards and/or into holes 915 when a mating force is applied. Alternatively or additionally, holes in a flexible membrane may reduce the force required to deflect that membrane and are an example of a feature that may be included in a contact region to tailor mechanical properties of the contact.

FIG. 9D is a view of the lower surface of array 900 including protrusions 910 and holes 915. As shown in FIG. 9D, the protrusions 910 have curved ends with a flat surface that contacts PCBs or other components. Such a shape is an example of a feature that can be formed by molding an elastomeric material to increase contact pressure by concentrating force. The shape of the protrusions 910 may be selected to have desired deformation when the array is connected to a PCB or other component.

The holes 915 are disposed around the protrusion 910, including four holes immediately surrounding the protrusion 910 and two pairs of holes positioned adjacent to the protrusion. The holes may be positioned to provide desired properties to the array. The shape and arrangement of the holes may allow for compression or deformation of the array in response to a mating force. The array may deform towards the centers of the holes when a mating force is applied. The positioning, size and arrangement of the holes may be selected to provide desired deformation or compression of the protrusion 910. For example, by providing additional holes, holes closer to the protrusion, or holes having larger diameters, the protrusion may compress more under a lower mating force.

Alternatively or additionally, the inner surfaces of holes through the contact array may facilitate conductive paths from one side of the array to another. Interior surfaces of the holes, for example, may be plated with a conductive material as part of a coating operation that deposits conductive material on opposing surfaces of the contact array.

FIG. 9D additionally shows extensions 902 which are adjacent to the protrusions 910 within the contact regions of contact array 900. The extensions 902 extend outward adjacent to the protrusions 910, such as to contact conductive elements (e.g., conductive shields) of an electrical connector which the contact array 900 is coupled to. As shown, the extensions 902 curve outward from the web 901 of the contact array to increase the contact pressure at the interface between the contact array 900 and conductive elements. In some embodiments, the extensions 902 may include further features for increasing the contact pressure at the interface between the contact array and the conductive elements, such as bumps, as described herein. The extensions 902 may wipe along conductive elements during a mating process.

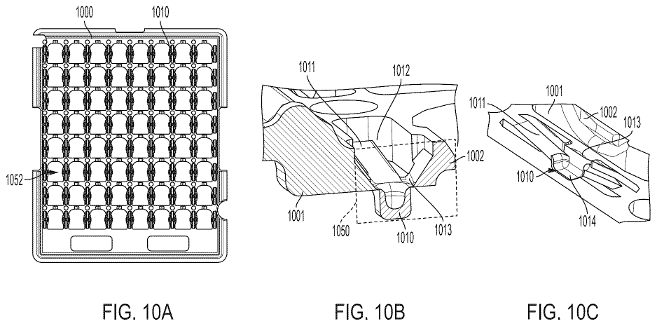

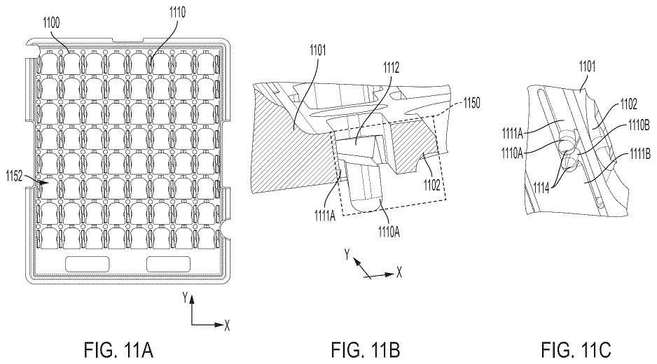

FIG. 10A is a bottom view of a compliant contact array having a plurality of contact regions, according to some embodiments. Array 1000 may be attached to an electrical connector as described herein, for example, as described with reference to FIGS. 1-3. In some embodiments, array 1000 may be mounted to an electrical connector via a retaining member. Array 1000 may be configured to contact a PCB or other electrical component when an electrical connector is connected the PCB or other component. Array 1000 has a plurality of protrusions 1010, which may contact the PCB or other component when the connector is pressed against that component.

FIG. 10B is a sectional view of a contact region of the compliant contact array of FIG. 10A. Contract region 1050 includes protrusion 1010 which is a portion of the compliant contact array 1000. As shown, contact region 1050 has a projection on the upper portion and a lower protrusion. The contact region 1050 is positioned at an edge of array 1000 and therefore may only contact a conductive element on the connector side of the array at one side of the contact region. Other contact regions of the array 1000 may contact multiple conductive elements of a connector, such as shown in FIG. 4B. The conductive element of the connector, for example, may extend into opening 1052 (FIG. 10A) of the contact array. As shown, the right side of the contact region has a projection shaped similarly to the projection in the contact region of FIG. 4B. The projection may similarly make contact with a conductive element of an electrical connector at a contact location. The size and/or shape of the projection, including the size of the opening in it and/or the thickness of the walls may differ from that shown in FIG. 4B to provide a higher or lower contact pressure at contact locations.

The protrusion 1010 has a concave interior cross-sectional edge and a convex exterior surface. The protrusion is rectangular in shape and is supported by two support members 1011. The support members 1011 are portions of the array configured as compliant beams. The support members are compliant such that the protrusion may move into cavity 1012 in response to a mating force. The protrusion 1010 is additionally supported by lateral support members 1013.

Features of support members 1011 and lateral support members 1013 may be selected to have specific properties. For example, the length, shape, thickness, and angles of the support members 1011 and lateral support members 1013 relative to a plane of the array may be selected to control the deformation or compression of the array responsive to a mating force. The features of the support members 1011 and lateral support members may be selected to provide a desired deflection of the protrusion 1010 into the cavity 1012.

The exterior surface of the contact region, including the bottom surface of the protrusion may be coated with a conductive material, such as may be applied with a conductive ink that is allowed to dry. When the contact array is compressed between the conductor and a substrate, such as a PCB, that conductive coating may form electrically conductive paths between conductive elements of a connector coupled to the array 1000 and conductive structures on the surface of the substrate. Optionally, the interior surface of the contact region may be coated with conductive materials.

FIG. 10C is a view of a lower surface of the array 1000 including protrusions 1010. As shown, the protrusion 1010 extends from the surface of the array, supported by the support members 1011 and the lateral support members 1013. The bottom surface 1014 of the protrusion may contact a PCB or other component when a connection is formed.

FIG. 10C additionally shows extensions 1002 which are adjacent to the protrusions 1010 within the contact regions of contact array 1000. The extensions 1002 extend outward adjacent to the protrusions 1010, such as to contact conductive elements (e.g., conductive shields) of an electrical connector which the contact array 1000 is coupled to. As shown, the extensions 1002 curve outward from the web 1001 of the contact array to increase the contact pressure at the interface between the contact array 1000 and conductive elements. In some embodiments, the extensions 1002 may include further features for increasing the contact pressure at the interface between the contact array and the conductive elements, such as bumps, as described herein. The extensions 1002 may wipe along conductive elements during a mating process.

FIG. 11A is a bottom view of a compliant contact array having a plurality of contact regions, according to some embodiments. Array 1100 may be attached to an electrical connector as described herein, for example, as described with reference to FIGS. 1-3. In some embodiments, array 1100 may be mounted to an electrical connector via a retaining member. Array 1100 may be configured to contact a PCB or other electrical component when an electrical connector is connected the PCB or other component. Array 1100 has a plurality of protrusions 1110, which may contact the PCB or other component when the connector is pressed against that component. The protrusions 1110 include a plurality of groups of two protrusions. The groups of two protrusions may be configured to contact a single conductive feature or separate, adjacent conductive features. Each contact region of the array 1100 may include a single group of two protrusions.

FIG. 11B is a sectional view of a contact region of the compliant contact array of FIG. 11A. Contract region 1150 includes protrusion 1110A which is a portion of the compliant contact array 1000. As shown, contact region 1150 has a projection and two lower protrusions. The contact region 1150 is positioned at an edge of array 1100 and therefore may only contact a conductive element on the connector side of the array at one side of the contact region. Other contact regions of the array 1100 may contact multiple conductive elements of a connector, such as shown in FIG. 4B. The conductive element of the connector, for example, may extend into opening 1152 (FIG. 11A) of the contact array. As shown, the right side of the contact region has a projection shaped similarly to the projection in the contact region of FIG. 4B. The projection may similarly contact a conductive element of an electrical connector at a contact location. The size and/or shape of the projection, including the size of the opening in it and/or the thickness of the walls may differ from that shown in FIG. 4B to provide a higher or lower contact pressure at contact locations.

The contact regions 1150 of the array 1100 include two protrusions, 1110A and 1110B, however in some examples a greater number of protrusions may be included, for example three, four, five or greater than five. Contact regions with multiple protrusions may be selected to reduce contact resistance and/or to increase reliability of electrical connections. As shown in FIG. 11B, the protrusion 1110A has a dome shaped end and is supported by support member 1111A. The end of the protrusion may contact a conductive feature of a mating component, such as a pad on a surface of a substrate. Support member 1111A is attached to the array and is located within cavity 1112. Protrusion 1110A may deflect into cavity 1112 responsive to a mating force. In some embodiments, the protrusion 1110A may deflect in the Y direction into the cavity 1112 responsive to a mating force. In some embodiments, the protrusion 1110A may deflect in the X direction, opposite the location of the support member 1111A, into cavity 1112. In some embodiments, the protrusion 1110A may deflect at least partially in the X and/or Y directions.

Features of support members 1111A may be selected to have specific properties. For example, the length, shape, thickness, and angles of the support member 1111A may be selected to control the deformation or compression of the array responsive to a mating force. The features of the support member 1111A may be selected to provide a desired deflection of the protrusion 1110A into the cavity 1112, for example the support member may be made thinner or longer to enable greater deflection for the same contact force, alternatively, the support member may be made thicker or shorter to reduce deflection.

The exterior surface of the contact region, including the bottom surface of the protrusion may be coated with a conductive material, such as may be applied with a conductive ink that is allowed to dry. When the contact array is compressed between the conductor and a substrate, such as a PCB, that conductive coating may form electrically conductive paths between conductive elements of a connector coupled to the array 1100 and conductive structures on the surface of the substrate. Optionally, the interior surface of the contact region may be coated with conductive materials.

FIG. 11C is a view of a lower surface of the array 1100 including protrusions 1110A and 1110B. As shown, the protrusions 1110A and 1110B extend from the surface of the array, supported by the respective support members 1111A and 1111B. As shown, the support members 1111A and 1111B of the adjacent protrusions 1110A and 1110B are located on opposite sides of the array and are elongated. The bottom surfaces 1114 of the protrusions may contact a PCB or other component when a connection is formed.

FIG. 11C additionally shows extensions 1102 which are adjacent to the protrusions 1110 within the contact regions of contact array 1100. The extensions 1102 extend outward adjacent to the protrusions 1110, such as to contact conductive elements (e.g., conductive shields) of an electrical connector which the contact array 1100 is coupled to. As shown, the extensions 1102 curve outward from the web 1101 of the contact array to increase the contact pressure at the interface between the contact array 1100 and conductive elements. In some embodiments, the extensions 1102 may include further features for increasing the contact pressure at the interface between the contact array and the conductive elements, such as bumps, as described herein. The extensions 1102 may wipe along conductive elements during a mating process.

FIG. 12A is a partially exploded view of an electrical connector having a compliant contact array, according to some embodiments. The connector 1200 includes housing 1201, conductor array 1202, compliant contact array 1220 and retaining member 1203. In this example, the conductor array 1202 may include contacts configured as signal conductors with compliant contact portions that make pressure mount connections to pads on a substrate, such as a PCB. Conductive elements configured as grounds may be interspersed within the contact array to provide shielding, to control impedance, or otherwise provide desirable properties that enable high speed signals to propagate through the connector to the substrate with high signal integrity.

The contact array, for example, may be similar to that shown in FIG. 3, in which ground conductors at least partially surround conductive elements that carry a signal. For connectors configured for differential signals, each pair of signal conductors may be at least partially surrounded by a ground conductor. The ground conductors may be coupled to one or more pads on the substrate that via the compliant contact array.

The mating interface for the connector is formed by a mating face 1210 of the connector 1200 and compliant contact array 1220. The mating interface is configured for pressure mounting to a PCB. The contacts of conductor array 1202 are compliant beams that are configured to contact pads on a PCB. A mating force may be applied to connector 1200 for contacts of the conductor array 1202 to connect to a PCB. The contacts of the conductor array 1202 are positioned in groups of two contacts. In some embodiments, the groups of two contacts may be differential pairs used for transmission of signals.

As in the example of FIG. 3, FIG. 12A shows a contact array 1220 extending in a plane with contact regions positioned to fit between adjacent ground conductors. The compliant contact array 1220 may be secured to the housing 1201 at the mating face 1210 by retaining member 1203. The retaining member 1203 includes bars which allow the protrusions 1221 and contacts of the conductor array 1202 to pass through and contact a PCB. The retaining member may engage with features of the housing 1201 such that it is retained on the connector 1200 and secures the compliant contact array to the connector. A retaining member, such as retaining member 1203 may be used to secure compliant contact arrays to electrical connectors, for example, the compliant contact arrays of FIGS. 4A-17D may be secured to an electrical connector using a retaining member.

When retaining member 1203 is attached to the connector, upper portions of each contact region are wedged between adjacent ground conductors. This wedging action applies a compressive force on the contact regions in a direction parallel to the plane of the contact array.

FIG. 12B is a section view of the connector of FIG. 12A. FIG. 12B illustrates the compliant contact array in this state. As shown the protrusions 1221 contact conductive shields 1204, forming electrical connections. Each shield 1204 surrounds a pair of conductors of the conductor array 1202. In some embodiments, the protrusions 1221 may include features along their interface with the shields 1204 to increase the contact pressure between the contact array 1220 and the shields 1204, for example bumps and/or a curved shape as described herein.

The compliant contact array 1220 may be made as in any of the examples described herein, such as by molding an elastic material in a liquid state and then applying a conductive coating. The conductive coating may be applied to at least exterior surfaces of the contact regions and may be applied in other regions if contact regions are to be interconnected.

As can be seen, the compliant contact array 1220 includes protrusions 1221, extending below the plane of the contact array. These protrusions are positioned in multiple rows. In this example, the protrusions are elongated in a direction parallel to the plane of the contact array. They are also elongated in a direction in which the compliant contact portions of the signal conductors are elongated. The protrusions are positioned such that adjacent pairs of signal conductors of the conductor array 1202 are separated by a protrusion 1221. Each pair of signal conductors may have a protrusion 1221 on each side.

FIG. 12B shows the connector in an unmated state in which tips of the protrusions 1221 and mating surfaces of the contact portions of the signal conductors extend beyond the surface of the connector. For reliable mating, the contact portions of the signal conductors are close to the surface of the connector. They are, however, sufficiently exposed in this example to be compressed when the connector is pressed against a substrate for mating. The protrusions 1221 also must make a reliable electrical connection, without requiring excessive force, when the connector is pressed into a mating state with sufficient compression of the contact portions of the signal conductors. FIG. 12B illustrates a geometry for the contact regions of the contact array that provides a desired amount of compression with a desired amount of force.

The protrusions 1221 include a cavity 1223 and a mating surface 1224. The mating surface 1224 may contact a PCB or other component when the connector 1200 is mated. The protrusions are rectangular in a plane of the compliant contact array 1220. The cross section of the protrusions 1221 have vertical sidewalls at the connector sides of the protrusions and a trapezoidal cross section above the vertical sidewalls. The protrusions additionally include angled surfaces 1225.

A mating force may be applied to connector 1200 to ensure electrical connection. The mating force may compress the protrusions and/or cause the protrusions to fold or collapse into cavities 1223. The connector may transfer a mating force to the protrusions via ribs 1205 of the housing.

The features of the protrusions 1221 may be selected to have desired properties. For example, the protrusions are elongated so as to separate adjacent signal conductors, which may reduce crosstalk. Further, the thickness of the contact array, in a direction perpendicular to the plane of the contact array, may be large enough that the contact array will be compressed sufficiently when the connector is pressed into its mating position in which contact portions of the signal conductors are compressed to generate an adequate mating force on the contact regions of the conductive array. However, features of the contact regions, such as the thickness of the sidewalls of the protrusions, the length of the protrusions, the angles of the trapezoidal portion, and/or the angles of angled surfaces 1225, may be selected to provide desired compression or deformation at specific mating forces. Despite a height that enables a relatively large amount of compression, the mating force may be low, such as less than 200 gm-force, for example.

FIG. 12C is a plot of the force versus displacement characteristics of a contact region, with a shape as shown in FIG. 12B. In this example, contact regions are spaced on a 2.8 mm pitch and the contact array may have an un-displaced nominal thickness of 0.35 mm. Curves 1250 and 1252 illustrate force on the contact array to achieve varying amounts of deflection as the contact arrays are compressed between two plates (i.e. the contact array was measured separate from a connector in which was designed to be used). Curve 1250 represents a contact array molded from liquid silicone rubber with 60 Shore A hardness. Curve 1252 represents a contact array molded from liquid silicone rubber with 35 Shore A hardness. In this configuration, the characteristics of the contact array are measured with the contact array separate from a connector housing.

In each of these two examples, the contact array may be displaced approximately 30-40 micrometers before substantial additional force is required for further compression. This inflection point at approximately 30-40 micrometers at a force of about 1 kgf may limit the working range of the contacts in the contact array.

Curve 1254 is a force-displacement curve for a contact array molded from liquid silicone rubber with 60 Shore A hardness in a test fixture representative of a connector in which silicone rubber may flow into spaces around the contact region when depressed. Such features, for example, may include holes as described in connection with FIG. 9D. As can be seen, structuring the connector housing or other components holding the contact array with space into which the silicone rubber may flow increases the amount of displacement that can occur before the force required for further displacement increases substantially.

This increase in the amount of displacement indicates a larger working range when the contact array is mounted within a structure with spaces adjacent the contact regions into which the elastic material of the contact regions can flow. FIG. 12C illustrates that by selection of the shape of the contact region and the connector support around the contact region, the working range and the mating force achieved may vary over a very large range.

In some examples, that force for 200(+200/−100) micrometers of displacement, might be set in a range that spans, for example, from around 5 gm or 6 gm up to over 2,000 gm per contact region by varying the materials used to form the contact array and/or incorporating or omitting features as described herein. The contact array and surrounding structures may be shaped, for example, to provide a force at the low end of this range, such as between 5 gm and 75 gm to reduce the overall force needed to hold a connector against a substrate. Alternatively, the contact array and surrounding structures may be shaped, for example, to operate under a force higher in this range, such as between 5 and 2,000 gm to ensure the normal force is sufficiently high to make a reliable electrical connection between contact regions and conductive structure against which those contact regions are pressed. Alternatively, the contact array and surrounding structures may be shaped to achieve mechanically simpler designs with force at the lower end of the range while achieving reliable electrical connections, such as between 75 and 500 gm/contact region.

In this example, thin sidewalls of the contact regions of the array as well as a hollow central portion of the contact region into which the base material near the distal end of the contact region may deflect when subjected to a compressive force enable a relatively low mating force.

Moreover, the tapered cross section visible in FIG. 12B provides desirable impedance properties that contributes to high signal integrity even at high speeds. When the connector is mounted to a substrate, compressive force on the contact region causes the tapered sidewalls to deflect outwards such that they are closer to being perpendicular to the plane of the array. In this state, the contact region may have a generally uniform width across the gap between the connector and the substrate to which it is mounted. This may provide in the contact region a uniform separation between the grounded conductive coating on the exterior surfaces of the contact region and adjacent signal conductors. As the separation between signals and adjacent ground impacts impedance and changes or mismatches in impedance can cause reflections or other issues that degrade signal integrity, shaping the contact regions to provide such a signal to ground spacing may enable higher speed from the connector.

FIG. 12D illustrates an alternative example of a contact array in which the contact regions are generally solid in cross section. When subjected to the same test that generated curve 1254, the force required to achieve 200 micrometers of displacement of the contact array may be significantly higher. The force required, for example, may be greater than 500 gm and may, for example, be thousands of gm, such as about 2,000 gm. Accordingly, by selecting the shape of the contact regions and how the contact array interacts with a connector, the mating force of a contact array may be set within a wide range, such as between about 5 gm to 2,000 gm per contact.

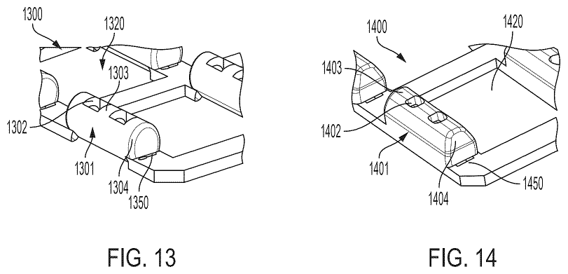

FIG. 13 is a view of a compliant contact array which may be used in a connector, according to some embodiments. The array 1300 may be used in a connector such as connector 1200 of FIGS. 12A-B and/or 100 of FIG. 1. As shown, the array 1300 includes protrusions 1301. The protrusions 1301 are shaped with a cross section that is a partial oval. Though not visible in the perspective view of FIG. 13, the protrusions may be hollow and include an internal cavity similar to that shown in FIG. 12B. The protrusions in this example have two rectangular holes 1302 formed at the distal sides of surface 1303. The holes may reduce the area of the contact location for increasing contact pressure and/or facilitate forming conductive paths from one side of the array to another, and/or providing more compliance of the contact surface such as greater deflection is achieved for a same force in comparison to a similar structure without those holes. While the holes 1302 are shown as rectangles, other shapes may be selected. The protrusions additionally include an angled edge 1304. The protrusions may compress and/or fold or collapse into their cavities responsive to a mating force.

The features of the protrusions 1301 may be selected to have desired properties. For example, the thickness of the sidewalls of the protrusions, the height of the protrusions, the length of the protrusions, the curvature of the protrusions, the size and locations of the holes 1302, and the angle and depth of angled edges 1304 may be selected to provide desired changes in shape of the contact regions at specific mating forces. In this example, an opening 1350 separates a protrusion from a web of the contact array over a substantial portion of the interface between the protrusion and the web. That substantial portion may be, for example, at least 50%, 60%, 75% or 80%, in some examples. The hole may reduce the contact force needed to compress the contact region.

As discussed above in connection with the configuration of FIG. 12A, the protrusions may be shaped to provide desired electrical properties in the contact regions of a connector, such as reducing crosstalk between adjacent conductor pairs or improving impedance uniformity between the connector and the substrate to which it is mounted. In some embodiments, contact array 1300 may be mounted to an electrical connector and the protrusions 1301 may contact conductive elements of the connector such as conductive shields. The protrusions 1301 may include features along their interface with the shields to increase the contact pressure between the contact array 1300 and the shields, for example bumps and/or a curved shape as described herein. The conductive element of the connector, for example, may extend into opening 1320 of the contact array.

FIG. 14 is a view of a surface of a compliant contact array which may be used in a connector, according to some embodiments. The array 1400 may be used in a connector such as connector 1200 of FIGS. 12A-B and/or 100 of FIG. 1. As shown, the array 1400 includes protrusions 1401. The protrusions 1401 are shaped with vertical sidewalls and a trapezoidal portion atop the vertical sidewalls. The protrusions include an internal cavity and have two rectangular holes 1402 formed at the top surface 1403. The protrusions additionally include angled surfaces 1404. The protrusions may compress and/or fold or collapse into their cavities responsive to a mating force. In this example, an opening 1450 at the interface between the contact region and the web of the contact array is also visible. As with opening 1350, opening 1450 may extend across a substantial portion of the interface between the protrusion and the web. Though such an opening is not visible in FIGS. 12A, 12B, such openings may similarly be present in other configurations.

The features of the protrusions 1401 may be selected to have desired properties. For example, the thickness of the sidewalls of the protrusions, the height of the protrusions, the length of the protrusions, the angles of the trapezoidal portion, the size and locations of the holes 1402, and/or the angles of angled surfaces 1404 may be selected to provide desired compression or deformation at specific mating forces. These features may additionally be selected to have desired electrical properties, for example reduced crosstalk between adjacent conductor pairs or improved impedance, as described herein. In some embodiments, contact array 1400 may be mounted to an electrical connector and the protrusions 1401 may contact conductive elements of the connector such as conductive shields. The protrusions 1401 may include features along their interface with the shields to increase the contact pressure between the contact array 1400 and the shields, for example bumps and/or a curved shape as described herein. The conductive element of the connector, for example, may extend into opening 1420 of the contact array.

FIG. 15A is a bottom view of a compliant contact array having a plurality of contact regions, according to some embodiments. Array 1500 may be attached to an electrical connector as described herein, for example, as described with reference to FIGS. 1-3 and/or FIG. 12. Array 1500 may be configured to be assembled to an electrical connector and contact a PCB or other electrical component when an electrical connector is pressure mounted to the PCB or other component. Array 1500 has a plurality of protrusions 1510, which may contact the PCB or other component when connected.

FIG. 15B is a detailed view of a contact region of the compliant contact array of FIG. 15A. The surface of the contact region 1550 may have a conductive coating applied, as described herein. When the contact array is compressed between the connector and a substrate, such as a PCB, that conductive coating may form electrically conducting paths between conductive elements of the connector and conductive structures on the surface of the substrate. The conductive element of the connector, for example, may extend into openings 1520 (FIG. 15A) of the contact array.

As shown, contact region 1550 is offset relative to the web 1501 of the contact array 1500. The contact region 1550 includes raised pedestal 1511 that supports protrusion 1510. The pedestal 1511 extends from the web 1501 of the contact array 1500. The pedestal 1511 allows for greater travel of the contact surface 1514 responsive to being pressed against a PCB or other conductive element during a mating process. Protrusion 1510, may collapse into itself, providing a first amount of travel. Protrusion 1510 may further collapse into pedestal 1511, providing additional travel in some examples. In some examples, depending on factors such as the wall thicknesses, the protrusion 1510 may also collapse into pedestal 1511, providing further travel.

In yet other examples, pedestal 1511 alternatively or additionally may collapse into web 1501, providing additional travel. Increased travel may increase the reliability of connections formed through the contact array, as reliable connections may be formed despite variation at least up to the travel distance in the separation of conductive elements to be connected through the contact array. Pedestals such as 1511 may be included in any contact array described herein, such as those described with reference to FIGS. 4A-14.

The contact region additionally includes bump 1512 positioned on sidewall 1513 which is configured to contact conductive elements of an electrical connector. The sidewall 1513 may also contact conductive elements of an electrical connector, such as by deforming around bump 1512. The bump 1512 provides increased contact pressure at the interface of the contact region and the conductive elements of the electrical connector and thus improves the electrical connection between the contact region 1550 and the conductive elements. In some examples, such as when pedestal 1511 collapses into web 1501, the bump 1512 may wipe along a conductive elements of an electrical connector during a mating process.

The contact region may include a corresponding bump on the opposite side of that shown in FIG. 15B. While one bump 1512 is shown, the contact region 1550 may include any number of bumps on sidewall 1513, which are configured to contact conductive elements of an electrical connector. For example, the sidewall 1513 may include two, three, four, five, or greater than five bumps. The bumps may be curved strips along the sidewall 1513 or may have different shapes, for example, circular bumps, rectangular bumps, or any other suitable shape. The bumps may extend along the height of the sidewall 1513, as shown, or may extend along the width of the sidewall 1513 and/or multiple bumps may be present along the height of the sidewall 1513. As shown, bump 1512 is positioned at the center of the sidewall 1513, however bumps may have different positions along the sidewall 1513, for example to the left or right sides sidewall 1513 in FIG. 15B.

Contact region 1550 includes protrusion 1510 which extends from pedestal 1511. Protrusion 1510 may have a major axis and a minor axis, with the major axis. The width along the minor axis of protrusion 1510 may be largest near the midpoint of protrusion 150, and generally decreasing towards the ends. In this example, protrusion 1510 has a diamond shape, with sidewalls extending from the pedestal 1511, and sloped surfaces extending from the sidewalls to a flat bottom surface 1514, which is configured to contact a conductive element (e.g., a PCB) during a mating process. The protrusion 1510 additionally includes fillets between the sidewalls and the pedestal 1511.

FIG. 15C is a sectional view of the contact region 1550 of contact array 1500. The view of FIG. 15C is taken along a direction parallel to the y-axis in FIG. 15A. As shown, the contact array includes cavity 1515 extending from the side of the contact array opposite the protrusion 1510. The cavity has a portion 1515a within the pedestal 1511 and a portion 1515b within the protrusion 1510. The shape of the cavity 1515 and the thickness of the walls of the contact array in the contact region may vary to control the deformation of the contact array during a mating process, as described herein. The protrusion and/or pedestal may deform to collapse into the cavity 1515 during a mating process. This behavior, for example, may be controlled by molding walls of contact region 1550 with thinner regions aligned with locations in which the walls fold in for contact region 1550 to collapse into itself.

FIG. 15D is a section view of a contact region 1550 of compliant contact array 1500 compressed between two components. The section view is taken along a direction parallel to the y-axis in FIG. 15A. For example, the contact array may be compressed between an electrical connector and a PCB, such as may occur when the connector mated to the PCB via a mating process such as described herein. As shown, the contact region 1550 compresses, and the protrusion 1510 and pedestal 1511 have collapsed into cavity 1515. The pedestal and protrusion have been pressed towards the web 1501 of the contact array. The protrusion 1510 has also flattened against PCB 210. This movement of the contact region 1550 enables portions of the contact region 1550, such as bumps 1512, in contact with the conductive element 1530, which is shown as a transparent outline, to wipe along the conductive elements 1530.

FIG. 16A is a bottom view of a compliant contact array having a plurality of contact regions, according to some embodiments. Array 1600 has a plurality of protrusions 1610, which may contact a PCB or other component when connected.

FIG. 16B is a view of a portion of the pressure mount face of an electrical connector including array 1600. Array 1600 is held to the connector via retaining member 1660, which includes bars extending between rows of protrusions 1610. In some embodiments, array 1600 may be pressed against the connector without a retaining member, such as described with reference to FIG. 1. The protrusions 1610 are positioned adjacent to conductive elements 1630 that surround pairs of contacts of the electrical connector. The array 1600 may electrically connect a PCB to the conductive elements 1630, for example via a conductive coating applied to the exterior surface of the array, as described herein. The conductive elements of the connector, extend into openings 1620 (FIG. 16A) of the contact array.

FIG. 16C is a detailed view of a contact region of the compliant contact array of FIG. 16A within an electrical connector. The surface of the contact region 1650 may have a conductive coating applied, as described herein. As shown, contact region 1650 is offset relative to the web 1601 of the contact array 1600. The contact region 1650 includes raised pedestal 1611 that supports protrusion 1610. The pedestal 1611 extends from the web 1601 of the contact array 1600. The pedestal 1611, as well as its offset location relative to the web, enables greater travel of the contact region 1650 responsive to a compressive force. When the contact array is integrated into a connector, increased travel may increase wipe between the contact region 1650 and conductive elements of the connector, such as conductive elements 1630, which are shown as transparent outlines.

In some examples, a contact region may include features that increase contact pressure at a surface of conductive component. In the example illustrated, contact region 1650 includes three bump 1612 positioned on sidewall 1613 which is configured to contact conductive element 1630 of an electrical connector. The bumps 1612 provide an increased contact pressure at the interface of the contact region and the conductive element 1630 and thus improves the electrical connection between the contact region 1650 and the conductive element 1630. Alternatively or additionally, the bumps 1612 may wipe along conductive element 1630 during mating. The contact region may include corresponding bumps on the opposite side of that shown in FIG. 16C. In the illustrated example, the bumps have an oblong shape and extend over a portion of the height of sidewall 1613, however other configurations may be used, as described herein. The sidewall 1613 may also contact conductive elements 1630, such as by deforming around bump 1612.

The bumps 1612 may be configured to improve the integrity of electrical signals passing through the electrical connector, when the connector is mated (e.g., to a PCB). For example, the number of bumps and/or the position of the bumps on sidewall 1613 may be selected to reduce crosstalk between adjacent signal contacts of an electrical connector. For example, multiple points of contact between the compliant contact array and the conductive elements may be provided (e.g., by including multiple bumps along the interface(s) between the compliant contact array and a conductive element of an electrical connector), and/or the distances between the points of contact between the compliant contact array and a conductive element may be reduced. Such positioning of bumps that in turn impacts contact points in a ground path may reduce the crosstalk between adjacent signal paths within an electrical connector. In the example of FIG. 16C, the conductive element 1630 is a shield for signal contacts of an electrical connector, and there are three bumps 1612 positioned on sidewall 1613, each of which is configured to contact each third of the end-to-end length of the conductive element 1630. Other configurations may be used, however. For example, a different number of bumps may be included to achieve a desired electrical performance (e.g., two bumps, four bumps, five bumps, six bumps, seven bumps or greater than seven bumps), and/or the placement of the contact points between the compliant contact array and the conductive element may be selected to achieve a desired electrical performance (e.g., at least one contact point at the middle quarter of the end-to-end length of the conductive element, multiple contact points at the middle half of the end-to-end length of the conductive element, at least on contact point at the first and last thirds of the end-to-end length of the conductive element, at least on contact point at the first and last quarters of the end-to-end length of the conductive element, at least on contact point at the first and last fifths of the end-to-end length of the conductive element, at least on contact point at the first and last eighths of the end-to-end length of the conductive element, among other configurations).

A similar principle will apply to the other compliant contact arrays described herein, including the compliant contact arrays of FIGS. 4A-17D. That is, the features of the compliant contact array at the interface between the compliant contact array and conductive elements of an electrical connector may be selected to achieve desired electrical performance (e.g., reduce crosstalk, and/or improve impedance uniformity between the connector and the substrate to which it is mounted).

In some examples, a contact region may include features that enhance wipe of one or more contact surfaces of a contact region along a pad on a mating component. Those features, for example, may include one or more projections with contact surfaces thereon. Those projections may be integrated into a contact region that changes shape as it is compressed during a mating process. Such a change in shape may result in a change in the lateral position of the contact surface. The projections may be shaped and positioned such that the change in the lateral position of the contact surface occurs while the contact surface presses against the mating component, resulting in wipe.

A contact region configured to provide wipe is illustrated, for example, in FIGS. 16A-16F. In the illustrated example, contact region 1650 includes protrusion 1610 which extends from pedestal 1611. The protrusion 1610 has multiple contact projections, including side contact projections 1620A and central contact projection 1620B. While the protrusion 1610 is shown with three contact projections, it may include any number of contact projections, for example two, four, five, or greater than five contact projections.

As shown, the side contact projections 1620A are smaller than the central contact projection 1620B and are angled outwards, while the central contact projection 1620B extends downwards from the pedestal 1611. The central contact projection 1620B extends away from pedestal 1611 farther than the side contact projections 1620A and therefore is configured to contact a conductive element (e.g., a PCB) before the side contact projections 1620A. When the central contact projection 1620B is pressed against a mating surface, a central portion of pedestal 1611 may deflect relatively more than lateral portions to which the side contact projections 1620A are coupled. As a result, side contact projections 1620A may contact the mating surface. As the contact projection 1610 is further pressed into the mating surface, the side contact projections will fold inward, toward the central contact projection 1620B. This folding action results in the contact location between each of the side contact projections 1620A and the mating surface moving towards the toward the central contact projection 1620B, creating wipe.

FIG. 16D shows a contact region 1650 of contact array 1600 in contact with PCB 210. As shown, the contact array is included within an electrical connector, and the connector may be mated to the PCB via a mating process such as described herein. As shown, all contact projections are in contact with the PCB 210, and the side contact projections 1620A have folded in toward the central contact projection 1620B. The side contact projections have wiped along the PCB 210 as their contact surfaces move inwards toward the central contact projection 1620B.

In the state shown in FIG. 16D, the contact region 1650 is compressed between an electrical connector and a PCB 210, and the pedestal 1611 and protrusion 1610 have compressed towards the web 1601 of the contact array. The bottom surfaces of the contact projections 1620A-B have also flattened against PCB 210. This compression of the contact region 1650 enables portions of the contact region 1650, such as bumps 1612, in contact with the conductive element 1630, which is shown as a transparent outline, to wipe along the conductive elements 1630. As shown, the bumps 1612 have deformed due to the compression of the contact region and the folding of the side contact projections 1620A. The leftmost and rightmost bumps 1612 are now angled partially to the left and right sides of FIG. 16D, demonstrating they have moved from the contact with PCB 210 and have wiped along conductive element 1630.

FIG. 16D is shaded according to the pressure generated between the compliant contact array and the conductive element 1630. The key at the left of FIG. 16D includes the shading and corresponding pressure levels in MPa of the compliant contact array. As shown, the bumps 1612 along the sidewall 1613 have the highest contact pressure against the conductive element 1630, with the pressures on the bumps ranging from about 2.5-6.6833 MPa. The pressure is concentrated at the lower portions of the bumps in the view of FIG. 16D, which is caused by the compliant contact array being pressed up and against the conductive elements 1630 during mating. The bumps increase the pressure at the interface between the compliant contact array and the conductive element 1630 and therefore improve the electrical connection between the compliant contact array and the conductive element.

The number, shape, positioning, dimensions, or features of the bumps 1612 may be selected to achieve a desired pressure along the interface with the conductive element during mating. For example, to increase the contact pressure, the bumps 1612 may be made to extend farther from the sidewall 1613 and/or the compliant contact array may be made thicker at the locations of the bumps 1612.

A similar principle will apply to the other compliant contact arrays described herein, including the compliant contact arrays of FIGS. 4A-17D. That is, the features of the compliant contact array may be selected to control the pressures at interfaces between a compliant contact array and conductive elements of an electrical connector (e.g., shields of an electrical connector) generated during mating of the compliant contact array, such as through the inclusion of bumps to increase the pressures at this interface.

FIG. 16E is a side view of a contact region of a compliant contact array, in a compressed state and shaded according to the sliding distance along a conductive element of an electrical connector. The key at the left of FIG. 16E includes the shading and corresponding sliding distances in mm of the compliant contact array along the conductive element. As shown, the bumps 1612 slid along the conductive element 1630, with the top portions of the bumps sliding the farthest along the conductive elements. As shown, the bumps have slid between about 0.0375-0.18836 mm along the surface of the conductive element 1630. This is due to these portions of the bumps being initially in contact with the conductive elements 1630 when the compliant contact array is in an uncompressed state. As described herein, when a compliant contact array wipes along a conductive element of an electrical connector and/or conductive feature (e.g., pad of a PCB), the electrical connection between the components is improved. Therefore, geometries of the compliant contact arrays may be selected to increase this wipe. In the example of FIG. 16E, the compliant contact array may be configured to increase the sliding distance of the bumps 1612 along the conductive element 1630 and/or to achieve a desired sliding distance, to improve the electrical connection between the components. For example, the height of the contact projections, the amount by which the contact projections extend below the conductive elements, the offset of the pedestal from the web, the positions of the bumps, the angles of the bumps, the size of the bumps, the shapes of the bumps and/or the number of bumps, may be selected to increase the wipe along the conductive elements 1630 and therefore improve the electrical connection between the compliant contact array and the conductive elements.

A similar principle will apply to the other compliant contact arrays described herein, including the compliant contact arrays of FIGS. 4A-17D. That is, the features of the compliant contact array may be selected to control the sliding distance during mating between a compliant contact array and conductive elements of an electrical connector (e.g., shields of an electrical connector).

FIG. 16F is a view of a contact region of a compliant contact array, in a compressed state and shaded according to the stress within the contact region. The key at the left of FIG. 16F includes the shading and corresponding stress, in MPa, of the compliant contact array along the conductive element of an electrical connector. It should be noted that the bumps of the contact region in the example of FIG. 16F extend along the height of sidewall 1613. As shown, the areas with the highest stress correspond areas where high contact pressures are desired, including at the surfaces of the contact protrusions and the bumps on the side of the contact region. At the high-stress areas at the surfaces of the contact protrusions, the stress ranges from about 1.5028-3.1469 MPa, and at the high-stress areas of the bumps, the stress ranges from about 1.2542-3.1496 MPa. The geometries of features of the compliant contact array may be selected to increase the stress generated at these areas, for example to yield greater contact pressures at during mating, and the compliant contact array may be configured to deform (e.g., through the folding of the contact protrusions and compression of the pedestal) so as to increase the contact pressure at these areas. Increasing the stress generated during mating at specific areas will help ensure a stable electrical connection is formed between the compliant contact array and a substrate (e.g., conductive pads of a PCB), and/or conductive elements of a connector.

A similar principle will apply to the other compliant contact arrays described herein, including the compliant contact arrays of FIGS. 4A-17D. That is, the features of the compliant contact array may be selected to control the stress at different locations, such as at interfaces between a compliant contact array and a substrate and/or conductive elements of an electrical connector (e.g., shields of an electrical connector) generated during mating of the compliant contact array.

As illustrated by the examples of FIGS. 13-16F, a contact array may provide a large range of travel of a contact surface with features that provide for multiple stages of collapse of a contact region. Those features may include one or more of a projection with a contact surface thereon, a projection with a contact surface thereon that collapses into itself, a pedestal on which the projection is mounted, a pedestal into which the projection collapses, and/or a pedestal offset from a web of the contact array that collapses into the web.

A further example of a compliant conductive array using these features is shown in FIGS. 17A-17D. FIG. 17A is a bottom view of a compliant contact array having a plurality of contact regions, according to some embodiments. Array 1700 may be attached to an electrical connector as described herein, for example, as described with reference to FIGS. 1-3, 12A-B, and/or 16B. Array 1700 may be configured to be assembled to an electrical connector and contact a PCB or other electrical component when an electrical connector is connected the PCB or other component. Array 1700 has a plurality of protrusions 1710, which may contact the PCB or other component when connected.

FIG. 17B is a detailed view of a contact region of the compliant contact array of FIG. 17A. The surface of the contact region 1750 may have a conductive coating applied, as described herein. When the contact array is compressed between the connector and a substrate, such as a PCB, that conductive coating may form electrically conducting paths between conductive elements of the connector and conductive structures on the surface of the substrate. As shown, contact region 1750 is offset relative to the web 1701 of the contact array 1700. The contact region 1750 includes raised pedestal 1711 that supports protrusion 1710. The pedestal 1711 extends from the web 1701 of the contact array 1700. The pedestal 1711 allows for greater travel of the contact region 1750 responsive to being pressed against a PCB or other conductive element during a mating process. This increased travel may facilitate reliable connections despite variability of the positions of the components to be connected. Alternatively or additionally, increased travel may increase the amount of wipe between the contact region 1750 and conductive elements of an electrical connector (e.g., conductive shields).

Sidewalls 1713 are curved and protrude outward from pedestal. The sidewalls 1713 may contact conductive elements of an electrical connector (e.g., conductive shields) which may extend into openings 1720 (FIG. 17A), as described herein. The curving of the sidewalls 1713 provides increased contact pressure at the interface of the contact region and the conductive elements of the electrical connector and thus improves the electrical connection between the contact region 1750 and the conductive elements. The sidewall 1713 may wipe along a conductive element of an electrical connector during a mating process.

Contact region 1750 additionally includes protrusion 1710 which extends from pedestal 1711. The protrusion 1710 has a dome shape, with multiple steps and a fillet between the protrusion and the pedestal 1711. The protrusion 1710 is configured to contact a conductive element (e.g., a PCB) during a mating process.

FIG. 17C is a sectional view of the contact region 1750 of contact array 1700. The view of FIG. 17C is taken along a direction parallel to the y-axis in FIG. 17A. As shown, the contact array includes cavity 1715 on the side of the contact array opposite the protrusion 1710. The shape and thickness of the cavity may vary to control the deformation of the contact array during a mating process as described herein. For example, the cavity may extend into the pedestal 1711 and/or into the protrusion 1710, enabling thinned walls, defining locations at which the walls fold when the contact region is compressed.

FIG. 17D is a view of a contact region 1750 of compliant contact array 1700 pressed against PCB 210. The connector may be mated to the PCB via a mating process such as described herein. As shown, the contact region 1750 compresses between the electrical connector and the PCB 210, and the protrusion 1710 and pedestal 1711 have compressed and moved into cavity 1715. The protrusion 1710 has also flattened against PCB 210. This compression of the contact region 1750 enables portions of the contact region 1750, such as sidewall 1713, in contact with the conductive element 1730, which is shown as a transparent outline, to wipe along the conductive elements 1730.

In addition to, or instead of, providing a large range of travel, contact regions that collapse into themselves may provide impedance control. Impedance may be controlled along the length of the conductive paths through an interconnect system in which conductive structures in two mating components are connected through a compliant contact array.

Impedance may be controlled by controlling spacing between conductive structures in the interconnect system. Spacing between signal and ground conductors and/or spacing between signal conductors may be controlled, for example. The spacing may be controlled to be substantially uniform along the length of a signal path between one or more conductive structures. Alternatively or additionally, the spacing may be controlled to be substantially uniform regardless of variation in the separation of the mating components, such as might result from tolerances in the manufacturing, assembly or operation of the interconnect system.

FIG. 17D illustrates how a collapsing contact array may be configured to provide uniformity. In this example, the bottom of protrusion 1710 has a width D₁. When protrusion 1710 collapses into itself, the collapsed structure has a substantially uniform width D₁ over a portion P₁ of its height, with a different width D₂ at the distal portion of the protrusion 1710, such as may provide a smaller contact surface for higher contact pressure. The collapsed structure may, as illustrated in FIG. 17D, be a pillar, which in this example has a hollow interior and a conductive coating on its exterior. The substantially uniform width may vary by +/−20% or less over portion P₁, or in some examples, +/−15% or less, 10% or less or 5% or less.

Portion P₁ may be relatively large, such as greater than 50% of the height of the compressed protrusion, or, in some examples, greater than 60%, 70%, 80% or 90% of the height. In an interconnect system, the conductive walls of protrusion 1710 may be parallel to other conductive structures in the interconnect system. In such a configuration, a substantially uniform width may translate into a substantially uniform separation between the walls of collapsed protrusion 1710 and a nearby conductive structure. Such uniform spacing may contribute to uniform impedance.

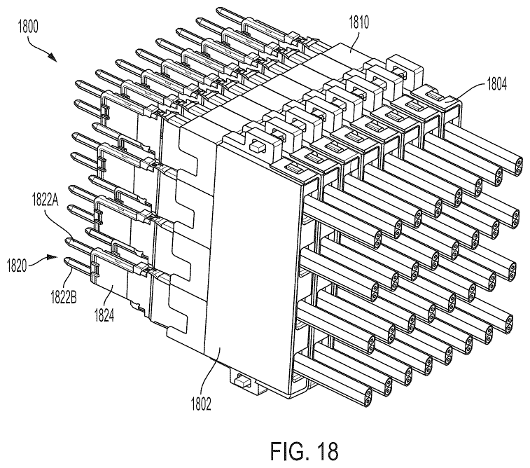

One or more of the techniques described herein for producing fine structures in a contact array, such as protrusions as described herein, may be used in other portions of electrical interconnect system. For example, a contact array with one or more contact regions may be used in a cable connector. The contact array may provide one or more electrically conducting paths between a cable shield and a ground structure of the connector, for example. FIG. 18 is an example cable connector which may include compliant conductive structures and performance of such a connector may be improved through the use of fine features as described herein. As illustrated in FIG. 18, the cable connector 1800 may include a plurality of cable wafers 1810, which may be held by one or more support members such as a housing. The cable connector 1800 includes multiple cable wafers, each supported by wafer housing 1802 on one side and a wafer shield 1804 on the opposite side. The wafer housings 1802 may include channels each configured to receive a cable module 1820. The wafer shield 1804 may be attached to the wafer housing 1802 such that the wafer modules are fixedly held in channels of the wafer housing 1802.

Each cable module 1820 may terminate a cable, which in this example is a twinax cable with two signal conductors and a surrounding cable shield (not visible in FIG. 18). The two signal conductors may be attached, such as by soldering to signal contacts, such as 1822A and 1822B in the module. The cable shield may be electrically connected to the module shield 1824. A contact array with an elastic base region with a conductive coating may be used to make the connection between the cable shield and the module shield. Fine features of the contact array may be used to position ground structures in desired locations to improve electrical performance of the module, even when the connector is miniaturized.

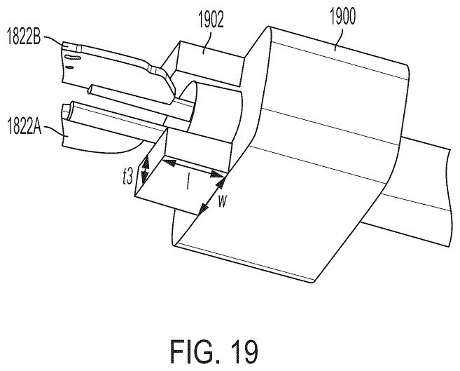

FIG. 19 is a perspective view of an attachment region of a cable module, with a compliant contact array 1900, according to some embodiments. In FIG. 19, module shield 1824 is hidden, but in operation, the cable shield is exposed at the end of the cable that passes through an opening in contact array 1900. Module shields 1824 may be placed on opposing sides of contact array 1900. The module shields may be secured in the module such that they press against exterior surfaces of contact array 1900. The interior surfaces of the opening in contact array 1900 press against the exposed cable shield in the opening, thereby making one or more conducting paths between the cable shield and the module shield through the contact array 1900. Though not illustrated in FIG. 19, the contact array 1900 may include one or more projections positioned to make contact the cable shield and/or the module shield.

As illustrated, the compliant contact array 1900 may include tabs 1902 extending towards the mating contact portions of the pair of conductive elements. Such a configuration may provide improved impedance uniformity of the connector and/or improved shielding at the attachment region. The tabs may be relatively fine and may be positioned where a conductive surface improves performance of the interconnection system, such as is shown in the example of FIG. 19 where the cable shield ends. The tabs, for example, may continue the signal to ground spacing within the cable into the transition region, even where the cable shield has been removed.

In some embodiments, a critical dimension of the tabs 1902 may be in the range of 0.1 mm to 1 mm, including any value or range of values within such range. As illustrated, a tab 1902 may have critical dimensions such as a length l, a width w, and a thickness t3. The critical dimensions such as the length l, width w, and thickness t3 may be of the same value or different values. Compliant contact structures made using techniques and materials as described herein may have sufficiently fine features to provide critical dimensions necessary to support a high density and/or miniaturized interconnect system.

The compliant contact array may have a conductive layer applied, such as a conductive ink. The conductive layer may be of a material that may flex with the insulative body portion.

The material of the conductive ink layer may be designed to have suitable conductivity and thickness for current flow paths between the module shields and/or cable shields. In some embodiments, the conductive layer may have a thickness in the range of 0.01 mm to 0.04 mm, including any value or ranges of value within such range. In some embodiments, the conductive layer may be a flexible carbon ink (e.g., 126-02(SP)AB) or may be a silver ink.

Other conductive coatings alternatively or additionally may be used. A conductive coating, for example, may be deposited in liquid or vapor form. The conductive coating may be deposited via chemical vapor deposition or sputtering, for example. Additionally, the conductive coating may be or contain other elements, such as tin, silver, gold or other noble metals, for example. The conductive coating may include multiple layers and/or multiple conductive coatings.

According to some embodiments, the components described herein may be used in high frequency interconnect systems. The frequency range of interest may depend on the operating parameters of the system in which such an interconnect is used, but may generally have an upper limit between about 15 GHz and 50 GHz, such as 25GHz, 30 or 40 GHz, although higher frequencies or lower frequencies may be of interest in some applications. Some connector designs may operate at higher frequency ranges, for example with an upper limit between 15 and 100 GHz, between 15 and 150 GHz, between 15 and 200 GHz, or between 15 and 250 GHz. Some connector designs may have frequency ranges of interest that span only a portion of this range, such as 1 to 10 GHz or 3 to 15 GHz or 5 to 35 GHz. The impact of unbalanced signal pairs, and any discontinuities in the shielding at the mounting interface may be more significant at these higher frequencies.

The operating frequency range for an interconnection system may be determined based on the range of frequencies that can pass through the interconnection with acceptable signal integrity. Signal integrity may be measured in terms of a number of criteria that depend on the application for which an interconnection system is designed. Some of these criteria may relate to the propagation of the signal along a single-ended signal path, a differential signal path, a hollow waveguide, or any other type of signal path. Two examples of such criteria are the attenuation of a signal along a signal path or the reflection of a signal from a signal path.

Other criteria may relate to interaction of multiple distinct signal paths. Such criteria may include, for example, near end cross talk, defined as the portion of a signal injected on one signal path at one end of the interconnection system that is measurable at any other signal path on the same end of the interconnection system. Another such criterion may be far end cross talk, defined as the portion of a signal injected on one signal path at one end of the interconnection system that is measurable at any other signal path on the other end of the interconnection system.

As specific examples, it could be required that signal path attenuation be no more than 3 dB power loss, reflected power ratio be no greater than −20 dB, and individual signal path to signal path crosstalk contributions be no greater than −50 dB. Because these characteristics are frequency dependent, the operating range of an interconnection system is defined as the range of frequencies over which the specified criteria are met.

Designs of an electrical interconnect are described herein that improve signal integrity for high frequency signals, such as at frequencies in the GHz range, to support high data rates including at 112 Gps and above, while maintaining high density, such as with a spacing between adjacent mating contacts on the order of 3 mm or less, including center-to-center spacing between adjacent contacts in a column of between 1 mm and 2.5 mm or between 2 mm and 2.5 mm, for example, among other contact spacings. Spacing between columns of mating contact portions may be similar, although there is no requirement that the spacing between all mating contacts in a connector be the same.

Some embodiments relate to a contact array for an electrical interconnection component. The contact array may comprise a contact region comprising an insulative elastic base region and a conductive coating on the base region; and an insulative web, integral with the contact region and supporting the contact region.

Optionally, the insulative web comprises an insulative elastomer.

Optionally, the insulative web is integrally formed with the base regions of the contact region.

Optionally, the insulative web comprises a thermoplastic.

Optionally, the base region comprises a first side and a second side; and the base region comprises a convex portion on the first side and a concave portion on the second side.

Optionally, a cross section of the concave portion includes multiple concave segments.

Optionally, the multiple concave segments have different radii.

Optionally, the base region comprises protrusions on the second side bounding the concave portion.

Optionally, the base region comprises a first side and a second side; and the base region comprises a hollow protrusion on the first side.

Optionally, the hollow protrusion comprises features configured to collapse when the contact array is compressed.

Optionally, the features configured to collapse comprise one or more concave surfaces on an exterior of the hollow protrusion.

Optionally, the hollow protrusion is configured to collapse via telescoping.

Optionally, the base region comprises a pedestal extending from the first side; and the hollow protrusion extends from the pedestal.

Optionally, the hollow protrusion is configured to collapse into itself when a compressive force is applied to the contact region.

Optionally, the hollow protrusion is configured to collapse into the pedestal when a compressive force is applied to the contact region.

Optionally, the base region is supported from the insulative web by one or more compliant support members.

Optionally, the contact region is a first contact region; the contact array comprises a plurality of contact regions, including the first contact region; each of the plurality of contact regions comprises an insulative elastic base region and a conductive coating on the base region; and the insulative web holds the plurality of contact regions.

Optionally, the conductive coating has a thickness between 10-500 μm.

Optionally, the conductive coating is a conductive ink.

Optionally, the conductive ink is a silver ink.

Optionally, the conductive coating is selectively applied to the plurality of contact regions such that the plurality of contact regions are electrically isolated from each other.

Optionally, a conductive coating further coats at least a portion of the insulative web such that at least a subset of the plurality of contact regions are electrically interconnected.

Optionally, the insulative elastomer has a hardness between 10 Shore A and 90 Shore A.

Optionally, the base region is configured to deform responsive to a mating force.

Optionally, the contact array is configured to compress between 0.1-1 mm in a direction parallel to the mating force, responsive to the mating force.

Optionally, the mating force is a force substantially parallel to a plane of the contact array.

Optionally, the mating force is a force substantially perpendicular to a plane of the contact array.

Optionally, the insulative web comprises one or more features configured to deform responsive to a mating force.

Optionally, he one or more features comprise one or more holes.

Optionally, the contact region is configured to electrically couple to one or more conductors.

Optionally, the contact region comprises at least one protrusion having a contact surface thereon the contact region is configured such that, in response to a compressive force in a first direction, the contact region deforms such that the contact surface moves in a second direction, transverse to the first direction.

Optionally, the protrusion is configured to compress up to 50% in a direction parallel to the compressive force.

Optionally, the contact region is configured to provide an electrical connection with 6-9 milliohms of resistance at a contact force of less than 10 grams-force between the contact region and the one or more conductors.

Optionally, the contact region is configured to generate a contact pressure of at least 1 MPa at an interface between the contact region and the one or more conductors.

Optionally, wherein the insulative elastic base region is an elastomer.

Optionally, the elastomer is silicone rubber.

Optionally, the insulative elastic base region has a resistivity of at least 10⁵ Ωcm.

Optionally, the base region of the contact region comprises a surface; the conductive coating is on the surface; and the base region is tapered with a narrower cross section at the surface comprising and a wider cross section in a more central portion.

Optionally, the contact region is configured for compression in a direction normal to the surface; and the base region has a tapered cross section in a plane that is coplanar with the direction normal to the surface.

Optionally, the elastic base region has a Poisson ratio of 0.5+/−0.1 .

Optionally, the elastic base region has a Poisson ratio of 0.5+/−0.05 .

Optionally, the elastic base region comprises an elastomer.

Optionally, a cross-sectional area of the contact region is configured to expand by less than 20% in a plane perpendicular to a direction of a mating force applied to the contact array.

Optionally, the contact array is molded of a material with a viscosity in an uncured state of between 0.015 Pa·s and 13000 Pa·s.

Some embodiments relate to a contact array for an electrical interconnection component, the contact array comprising: a contact region comprising an insulative elastomer base region and a conductive coating on the base region, wherein the insulative elastomer base of the contact region comprises at least one of a variation in thickness of the base region or a variation in surface contour of the base region on one or more surfaces of the insulative elastomer, and the conductive coating comprises a conductive ink.

Optionally, the base region comprises a first side and a second side, opposite the first side; the base region on the first side is concave and the base region on the second side is convex.

Optionally, the contact region comprises an opening from the first side to the second side.

Optionally, the contact region is configured to deform responsive to a mating force applied to the contact array.

Optionally, the contact region is configured to deform at least partially towards the opening responsive to the mating force.

Optionally, the contact array comprises an insulative elastomer member extending in a plane the contact region is a first contact region; the contact array comprises a plurality of contact regions, including the first contact region; each of the plurality of contact regions comprises an insulative elastomer base region of the insulative elastomer member and a conductive coating on the base region, the insulative elastomer base of each of the plurality of contact regions comprises at least one of a variation in thickness of the base region or a variation in surface contour of the base region on one or more surfaces of the insulative elastomer member.

Optionally, the base region comprises a protrusion from a first side of the insulative elastomer member; and the opening extends through the protrusion.

Optionally, the contact array comprises insulative elastomer member extending in a plane; the insulative elastomer member comprises the base region; the insulative elastomer member has an average thickness in a direction perpendicular to the plane; and the contact region comprises a region with a thickness in the direction perpendicular to the plane that is less than 60% of the average thickness.

Optionally, the contact array is configured for connection to an electrical connector; and a surface of the contact region is configured to contact a conductive element of the electrical connector.

Optionally, the surface of the contact region configured to contact the conductive element comprises one or more features configured to increase the contact pressure between the contact region and the conductive element.

Optionally, the one or more features configured to increase the contact pressure include one or more of: one or more bumps projecting from the surface, the surface extending from the contact region, and/or the surface curving outwards from the contact region.

Optionally, the one or more features are positioned on the surface of the contact array to reduce crosstalk within the electrical connector.

Optionally, the surface of the contact region is configured to wipe along the conductive element of the electrical connector during a mating process for the electrical connector.

Optionally, the surface of the contact region is configured to wipe 0.01-0.5 mm along the conductive element of the electrical connector during a mating process for the electrical connector.

Optionally, the base region comprises a stepped protrusion from the first side.

Optionally, the base region is elongated in a direction parallel to a plane of the contact array.

Optionally, the contact region is configured to contact a conductive element at multiple points.

Some embodiments relate to a contact array for an electrical interconnection component, the contact array comprising: an insulative elastomer member extending in a plane, the insulative elastomer member comprising a plurality of integral contact regions, wherein each of the plurality of contact regions comprises at least one insulative elastomer protrusion projecting transverse to the plane; and conductive coating on the at least one insulative elastomer protrusion of the plurality of contact regions.

Optionally, the at least one insulative elastomer protrusion of the plurality of contact regions is deformable towards the plane of the insulative elastomer member at least 0.10 mm under a force of 0.1 N.

Optionally, an insulative elastomer protrusion of the at least one insulative elastomer protrusion of each of the plurality of contact regions projects from the insulative elastomer member at least 0.2 mm.

Optionally, the separation to deflection ratio of the insulative elastomer protrusion is less than 2.

Optionally, the insulative elastomer protrusion has a Poisson's ratio of less than 0.5.

Optionally, the insulative elastomer member comprises a first side and a second side, and the protrusions of the plurality of contact regions extend towards the second side.

Optionally, adjacent contact regions of the plurality of contact regions are configured to contact different portions of a conductive element at the first side of the insulative elastomer member.

Optionally, contact regions of the plurality of contact regions are configured to contact multiple conductive elements at the first side of the insulative elastomer region.

Optionally, contact regions of the plurality of contact regions are configured to contact multiple conductive elements at the second side of the insulative elastomer region.

Optionally, protrusions of the plurality of contact regions have different shapes.

Optionally, the protrusions are configured to deform responsive to a mating force applied to the contact array.

Optionally, the insulative elastomer member is configured to couple to a connection component comprising a plurality of signal conductors and ground conductors.

Optionally, contact regions of the plurality of contact regions are configured to electronically couple to signal conductors of the plurality of signal conductors.

Optionally, contact regions of the plurality of contact regions are configured to electronically couple to ground conductors of the plurality of ground conductors.

Optionally, the protrusions comprise a concave exterior surface bounding a cavity and having a contact surface thereon; and the contact regions are configured to deform by the contact surface at least partially collapsing into the cavity.

Optionally, the plurality contact regions each comprises: a platform, wherein: the protrusion extends from the platform; the platform comprises a second cavity, in communication with the cavity of the protrusion, therein; and the contact region is configured to deform by the protrusion at least partially collapsing into the second cavity.

Optionally, the contract array comprises a web extending in a plane and connecting the plurality of contact regions; for each of the plurality of contact regions, the platform is coupled to the web and is offset from the plane of the web; and the contact region is configured to deform by the platform moving towards the plane of the web.

Optionally, for each of the plurality of contact regions: the contact region deforms, at least in part, by deformation of the protrusion; and the protrusion is configured to deform into a pillar having a width varying less than 10% over at least 70% of its height.

Optionally, the protrusion of each of the plurality of contact regions comprises a plurality of contact projections projecting transverse to the plane.

Optionally, the contact projections include a central projection and two side projections, the central projection extending beyond the two side projections transverse to the plane.

Optionally, during a mating process for connecting the contact array to one or more conductive elements, the central projection is configured to contact the one or more conductive elements before the side projections.

Optionally, the side projections are configured to bend towards the central projection as the contact array is urged against the one or more conductive elements during the mating process.

Optionally, the side projections are configured to wipe along the one or more conductive elements as the contact array is urged against the conductive elements during the mating process.

Optionally, the side projections are configured to wipe 0.01-0.5 mm along the one or more conductive elements as the contact array is urged against the conductive elements.

Some embodiments relate to an electronic system. The electronic system may comprise a substrate comprising a surface and a plurality of conductive pads on the surface; an interconnection component comprising a plurality of conductive members; and a contact array between the substrate and the interconnection component electrically connecting the plurality of conductive members to respective pads of the plurality of conductive pads, the contact array comprising an insulative elastomer base comprising a first side, adjacent the substrate and a second, opposite the first side, adjacent the interconnection component, wherein the contract array comprises a plurality of contact regions, each of the contact regions comprising a variation in a surface contour of the first side and/or the second side of the insulative elastomer base and a conductive coating on the insulative elastomer base.

Optionally, each of the plurality of contact regions is shaped differently on the first side and the second side.

Optionally, each of the plurality of contact regions is shaped on the second side to engage a respective conductive member of the plurality of conductive members.

Optionally, each of the plurality of contact regions is shaped on the second side to wipe along the respective conductive member of the plurality of conductive members.

Optionally, each of the plurality of contact regions is shaped on the first side to at least partially collapse when pressed against a conductive pad of the plurality of conductive pads.

Optionally, each of the plurality of contact regions comprises a protrusion extending in a direction from the second side towards the first side.

Optionally, the protrusions are stepped protrusions.

Optionally, the protrusions are supported by one or more compliant support members.

Optionally, each of the plurality of contact regions comprise a membrane extended from the fist side, and the protrusions are disposed on the membranes.

Optionally, the contact regions are elongated in a direction parallel to a plane of the contact array.

Optionally, the contact array comprises a plurality of features adjacent to the contact regions, the features configured to deform responsive to a mating force applied to the contact array.

Optionally, the features comprise holes, and the contact array is configured to deform, in part, towards the holes.

Some embodiments relate to a method of connecting an electrical connector to a substrate with one or more conductive surfaces. The method may comprise positioning the connector with a first surface of the connector facing a surface of the substrate and an elastomer contact array with protrusions aligned with the conductive surfaces; urging the connector towards the substrate such that the elastomer contact array contacts the one or more conductive pads of the substrate; applying a mating force to the connector, whereby the protrusions of the elastomer contact array are deformed.

Optionally, the mating force is substantially perpendicular to a plane of the substrate.

Optionally, the protrusions each comprise a cavity bounded by a respective wall; and the protrusions are each deformed by at least partially collapsing into the cavity.

Optionally, bringing the connector into contact with the substrate comprises: connecting one or more conductors of the connector to one or more conductive features of the substrate.

Optionally, applying the mating force to the connector comprises securing one or more fasteners to the connector.

Some embodiments relate to a method of manufacturing an electrical connector. The method may comprise molding a contact array comprising a plurality of elastomer contact regions; applying a conductive coating to at least the plurality of contact regions of the contact array, the conductive coating comprising a conductive ink.

Optionally, molding comprises molding liquid silicone rubber.

Optionally, molding comprises molding the plurality of elastomer contact regions and an insulative web connecting the plurality of elastomer contact regions as an integral member.

Optionally, molding comprises molding the plurality of elastomer contact regions over an insulative web.

Optionally, applying a conductive coating comprises selectively applying the conductive coating to the plurality of contact regions of the contact array.

Optionally, the conductive ink comprises silver.

Optionally, A method for assembling an electrical connector, the method comprising providing a contact array comprising a plurality of elastomer contact regions; assembling the contact array with a housing of the electrical connector, such that the contact array is supported by the housing.

Optionally, assembling the contact array with the housing comprises connecting one or more conductors supported by the housing to one or more contact portions of the contact array.

Optionally, connecting the one or more conductors to the one or more contact portions comprises connecting cable shields to contact portions of the contact array.

Optionally, assembling the contact array with the housing comprises: assembling the contact array with a retaining member; and assembling the retaining member with the housing.

Optionally, the retaining member is positioned between the contact array and the housing.

Optionally, the contact array is positioned between the retaining member and the housing.

Although details of specific configurations of compliant contact arrays and elements are described above, it should be appreciated that such details are provided solely for purposes of illustration, as the concepts disclosed herein are capable of other manners of implementation. In that respect, various designs described herein may be used in any suitable combination, as aspects of the present disclosure are not limited to the particular combinations shown in the drawings.

Having thus described several embodiments, it is to be appreciated various alterations, modifications, and improvements may readily occur to those skilled in the art. Such alterations, modifications, and improvements are intended to be within the spirit and scope of the invention. Accordingly, the foregoing description and drawings are by way of example only.

Various changes may be made to the illustrative structures shown and described herein. For example, a compliant contact array was described in connection with a connector attached to a printed circuit board. A compliant contact array may be used in connection with any suitable component mounted to any suitable substrate. As a specific example of a possible variation, a compliant contact array may be molded of a viscoelastic material.

Manufacturing techniques may also be varied.

Techniques for making multiple contacts in an interconnect system have been illustrated in connection with a pressure mount connector and a cable connector. These techniques may be used in other connectors, such as mezzanine connectors, chip sockets, backplane connectors, stacking connectors, mezzanine connectors, I/O connectors, or right angle connectors. Additionally, examples of an interconnect system in which a compliant contact array is used to make ground connections in a pressure mount connector were provided. Applicability of the techniques described herein is not limited to pressure mount connectors and are not limited to making ground connections. A contact array made with materials and shapes as described herein may be used to make signal connections, for example.

The present disclosure is not limited to the details of construction or the arrangements of components set forth in the foregoing description and/or the drawings. Various embodiments are provided solely for purposes of illustration, and the concepts described herein are capable of being practiced or carried out in other ways. Also, the phraseology and terminology used herein are for the purpose of description and should not be regarded as limiting. The use of “including,” “comprising,” “having,” “containing,” or “involving,” and variations thereof herein, is meant to encompass the items listed thereafter (or equivalents thereof) and/or as additional items.

What is claimed is:

1. A contact array for an electrical interconnection component, the contact array comprising:
a contact region comprising an insulative elastic base region and a conductive coating on the base region; and
an insulative web, integral with the contact region and supporting the contact region.

2. The contact array of claim 1, wherein:
the insulative web comprises an insulative elastomer.

3. The contact array of claim 2, wherein:
the insulative web is integrally formed with the base regions of the contact region.

4. (canceled)

5. The contact array of claim 1, wherein:
the base region comprises a first side and a second side; and
the base region comprises a convex portion on the first side and a concave portion on the second side.

6-8. (canceled)

9. The contact array of claim 1, wherein:
the base region comprises a first side and a second side; and
the base region comprises a hollow protrusion on the first side.

10. The contact array of claim 9, wherein:
the hollow protrusion comprises features configured to collapse when the contact array is compressed.

11. (canceled)

12. The contact array of claim 10, wherein:
the hollow protrusion is configured to collapse via telescoping.

13-16. (canceled)

17. The contact array of claim 1, wherein:
the contact region is a first contact region;
the contact array comprises a plurality of contact regions, including the first contact region;
each of the plurality of contact regions comprises an insulative elastic base region and a conductive coating on the base region;
the insulative web holds the plurality of contact regions;
the conductive coating has a thickness between 10-500 μm; and
the conductive coating comprises a silver ink.

18-32. (canceled)

33. The contact array of claim 1, wherein:
the contact region is configured to electrically couple to one or more conductors; and
the contact region is configured to provide an electrical connection with 6-9 milliohms of resistance at a contact force of less than 10 grams-force between the contact region and the one or more conductors.

34-63. (canceled)

64. A contact array for an electrical interconnection component, the contact array comprising:
an insulative elastomer member extending in a plane, the insulative elastomer member comprising a plurality of integral contact regions, wherein each of the plurality of contact regions comprises at least one insulative elastomer protrusion projecting transverse to the plane; and
conductive coating on the at least one insulative elastomer protrusion of the plurality of contact regions.

65. The contact array of claim 64, wherein:
the at least one insulative elastomer protrusion of the plurality of contact regions is deformable towards the plane of the insulative elastomer member at least 0.10 mm under a force of 0.1 N.

66-70. (canceled)

71. The contact array of claim 64, wherein:
the insulative elastomer member comprises a first side and a second side, and the protrusions of the plurality of contact regions extend towards the second side; and
contact regions of the plurality of contact regions are configured to contact multiple conductive elements at the first side of the insulative elastomer region.

72-74. (canceled)

75. The contact array of claim 64, wherein:
the insulative elastomer member is configured to couple to a connection component comprising a plurality of signal conductors and ground conductors.

76. The contact array of claim 75, wherein:
contact regions of the plurality of contact regions are configured to electronically couple to signal conductors of the plurality of signal conductors.

77. (canceled)

78. The contact array of claim 64, wherein:
the protrusions comprise a concave exterior surface bounding a cavity and having a contact surface thereon; and
the contact regions are configured to deform by the contact surface at least partially collapsing into the cavity.

79. The contact array of claim 78, wherein:
the plurality contact regions each comprises:
a platform,
wherein:
the protrusion extends from the platform;
the platform comprises a second cavity, in communication with the cavity of the protrusion, therein; and
the contact region is configured to deform by the protrusion at least partially collapsing into the second cavity.

80. (canceled)

81. The contact array of claim 64, wherein:
for each of the plurality of contact regions:
the contact region deforms, at least in part, by deformation of the protrusion; and
the protrusion is configured to deform into a pillar having a width varying less than 10% over at least 70% of its height.

82. The contact array of claim 64, wherein:
the protrusion of each of the plurality of contact regions comprises a plurality of contact projections projecting transverse to the plane.

83. The contact array of claim 82, wherein the contact projections include a central projection and two side projections, the central projection extending beyond the two side projections transverse to the plane.

84. The contact array of claim 83, wherein, during a mating process for connecting the contact array to one or more conductive elements, the central projection is configured to contact the one or more conductive elements before the side projections.

85. The contact array of claim 84, wherein the side projections are configured to bend towards the central projection as the contact array is urged against the one or more conductive elements during the mating process.

86. The contact array of claim 85, wherein the side projections are configured to wipe along the one or more conductive elements as the contact array is urged against the conductive elements during the mating process.

87. (canceled)

88. An electronic system, comprising:
a substrate comprising a surface and a plurality of conductive pads on the surface;
an interconnection component comprising a plurality of conductive members; and
a contact array between the substrate and the interconnection component electrically connecting the plurality of conductive members to respective pads of the plurality of conductive pads, the contact array comprising an insulative elastomer base comprising a first side, adjacent the substrate and a second, opposite the first side, adjacent the interconnection component, wherein the contact array comprises a plurality of contact regions, each of the contact regions comprising a variation in a surface contour of the first side and/or the second side of the insulative elastomer base and a conductive coating on the insulative elastomer base.

89. The electronic system of claim 88, wherein:
each of the plurality of contact regions is shaped differently on the first side and the second side.

90. (canceled)

91. The electronic system of claim 88, wherein:
each of the plurality of contact regions is shaped on the second side to engage a respective conductive member of the plurality of conductive members; and
each of the plurality of contact regions is shaped on the second side to wipe along the respective conductive member of the plurality of conductive members.

92. The electronic system of claim 88, wherein:
each of the plurality of contact regions is shaped on the second side to engage a respective conductive member of the plurality of conductive members; and
each of the plurality of contact regions is shaped on the first side to at least partially collapse when pressed against a conductive pad of the plurality of conductive pads.

93. The electronic system of claim 88, wherein:
each of the plurality of contact regions comprises a protrusion extending in a direction from the second side towards the first side.

94-95. (canceled)

96. The electronic system of claim 93, wherein:
each of the plurality of contact regions comprise a membrane extended from the first side, and
the protrusions are disposed on the membranes.

97. The electronic system of claim 88, wherein:
the contact regions are elongated in a direction parallel to a plane of the contact array.

98-116. (canceled)
